(19) United States
(12) Patent Application Publication
(10) Pub. No.: US 2007/0165384 A1
(43) Pub. Date: Jul. 19, 2007

(54) Data gathering platform

(76) Inventor: Mark Willard Vejnar, Riverside, CA (US)

Correspondence Address: Robert N. Schlesinger, 7289 Meadowlark Place, Rando Cucamonga, CA, 91701, US

(21) Appl. No.: 11/331,646

(22) Filed: Jan. 14, 2006

(51) Int. Cl. H05K 5/00

(52) U.S. Cl. 361/724; 312/271; 312/294; 361/600; 361/679; 73/855

(57) ABSTRACT

This Data Gathering Platform is used to conveniently house and to efficiently utilize devices, such as those that are used to take a set of measurements and to store and evaluate the measurements. This Data Gathering Platform has embodiments with and without a handle, and with a detachable handle, and a folding hinged handle. This Data Gathering Platform has applications in numerous fields, including the construction and real property appraisal industries, and the movie industry and nursing and medical charting industries.

### FIELD OF THE INVENTION

This “Data Gathering Platform” will hereinafter be referred to as a proper noun with the first letter of each word capitalized, throughout this specification and its appended claims.

This invention, entitled Data Gathering Platform, was devised and invented by Mark Willard Vejnar, and relates to a new and useful type of platform or the like, designed particularly for holding and housing devices and instruments that measure, record, and process lengths and distances that are used in the construction and real estate industries, and other industries such as the real estate appraisal industry, where length measurements may be used and processed as part of a report. The Data Gathering Platform may be used to conveniently hold and house other types of devices and instruments, such as movie cameras (30), remote activators (31), medical charting instrumentation, and the like, for more efficient and ergonomic use.

### BACKGROUND OF THE INVENTION AND DESCRIPTION OF THE RELATED ART INCLUDING INFORMATION DISCLOSED UNDER 37 CFR 1.97 AND 1.98

Heretofore, when a construction worker wants to measure a length or a square footage, such as the square footage needed to carpet a room, tile a room, or wallpaper a set of walls, a tape measure tool or a measuring wheel would be used to get the raw data estimate, and then the data would typically be entered into a notebook, scrap of paper, or the like, for evaluation and a set of calculations to be manually performed at site or later. This cumbersome method has been used and largely unchanged for many centuries. Nowadays, there are tools that may make such chores easier, quicker, and more accurate, but the tools are not designed for optimal compatibility with each other or for coordinated or efficient use. Therefore, even using modern measuring and computational tools, one may become frustrated switching from one tool and its format, to another, and yet another tool with its format, and during this switching of tools during an application, measured distances may change or may be difficult to re-align to the same position, and errors are more likely to occur. This problem and its consequent fumbling has been enough to discourage and dissuade construction workers from using the best and most modern tools available.

Heretofore, when a real property appraiser wants to appraise a real property, the appraiser needs to measure the square footage of the property's rooms, and other relevant features. For many commercial and business properties, the cubic footage must also be measured, calculated, and illustrated. These measurements are most often done with a tape measure or a measuring wheel to get the raw data estimate, and then the data would typically be entered into a notebook, scrap of paper, or the like, for evaluation and a set of calculations to be manually performed later. This cumbersome method has been used and largely unchanged for many decades. Nowadays, there are tools that may make such chores easier, quicker, and more accurate, but the tools are not designed for optimal compatibility with each other or for coordinated and efficient use. Therefore, even using modern measuring and computational tools, one may become frustrated switching from one tool and its format, to another, and yet another tool and its format, and during this switching of tools during an application, measuring distances may be difficult to realign to the same position, and errors are more likely to occur. This problem and its consequent fumbling has been enough to sometimes discourage and dissuade real property appraisers from using the best and most modern tools available, and have often lead to the inefficient use of the modern instruments and tools.

As indicated above, in the construction industry, when preparing to lay carpeting, one may take measurements of the dimensions of the room to be carpeted, and thereby calculate the square footage of carpeting needed for the job, and one may determine the shape of the carpeting layout, as it will be installed. This is usually done with a tape measure or a measuring wheel and with calculations done on scraps of paper. Although there are modern measuring tools available, and instruments such as handheld computers that are available to make the job easier, the measurements and computations remain somewhat cumbersome because the modern tools and instruments are not optimally compatible and their use remains uncoordinated and independent.

Another example indicated above, in the real property appraisal industry, when preparing to appraise a property, the real estate appraiser must take accurate measurements of the size of the rooms, and the square footage of the real property, and the cubic footage of certain commercial and other special properties. This is usually done with a tape measure or a measuring wheel, and notes and calculations are often done in notebooks. Although there are modern measuring tools and instruments, such as handheld computers, available to make the job easier, quicker, and more accurate, the measurements and computations are generally done using antiquated methods, and those that venture into the modern era, and use said modern tools and instrumentation, are hampered with the problem that the tools and instruments are not designed to be used in a optimally compatible and coordinated and efficient manner. Users of these modern tools and instruments therefore must switch from one tool or instrument to another, thereby making the process cumbersome, clumsy, fumbling, more time-consuming, and more frustrating, and they risk having increased frequency and size of errors.

For both the above identified example applications, one would optimally use a measuring device to measure the needed lengths, and said lengths would then be entered into a handheld computer (29), or transmitted into said computer (29) via a wireless means such as Bluetooth, for storage in the computer's (29) data bank, and for further computational analysis with other related data, to compose a sketch or the like, and a report on said analysis. The data or its analysis may then be transferred electronically for further analysis, storage, or printing. For the application of the Data Gathering Platform used in the real property appraisal industry, the Data Gathering Platform may also house a camera (30), and preferably a digital camera (30) to record images of the real property and selected aspects of the property. The handheld computer (29) may have a work sheet or template for a set of forms and reports, so that they may have the field information entered and the forms and reports may be readied in-the-field.

### BRIEF SUMMARY OF THE INVENTION

In trying to solve the above-described and illustrative example problems and disadvantages from the construction and real estate appraisal industries, and within the scope of this invention, the inventor, Mark Willard Vejnar, conceived, devised, invented, and engineered a new and useful Data Gathering Platform for effectively, efficiently, conveniently, ergonomically, and compatibly holding, housing, and using modern measuring tools (e.g., 28) and support instrumentation, such as a handheld computer (29), and a camera (30).

The Data Gathering Platform is an ergonomically designed platform that is especially designed to optimally hold and house the key tools and instruments needed to perform selected measuring and recording tasks, and most particularly in the construction and real property appraisal fields. The Data Gathering Platform is designed to be easily grasped, held, and pointed, and may optimally have a handle (17). Said handle (17) is optimally detachable and ergonomically designed like a pistol grip (17) with finger channels (18). The placement of the tools and instruments on the top surface, i.e. the top plate (1), of the Data Gathering Platform is designed for ease-of-use, and for optimal efficiency and security of the tools and instruments. In most simple and the preferred embodiments of the Data Gathering Platform, a laser measuring tool (28) is screw-fitted onto the right portion of the Platform top plate (1). In these embodiments, a camera (30) is screw fitted onto the left portion of the top plate (1), and typically at the front portion. A handheld computer (29) is held into place with a set of clamps (2 and 5) on the left portion of the Platform, and typically behind the camera (30). The local and design engineered placement of these key tools and instruments affords the user a quicker, easier, and efficient means of taking measurements and processing said measurements into useful information, such as a set of sketches, a report, or a data set. The Data Gathering Platform effectively takes a loosely related set of tools and instruments, and bundles them together in a closely related and ergonomic manner to make their use easy, compatible, coordinated, efficient, and useful.

### BRIEF DESCRIPTION OF THE SEVERAL VIEWS OF THE DRAWINGS

The drawing figures listed and described below, and included in this specification include, in many cases, some optional components or optional aspects of certain components. The inventive concepts are intended to include the simplest and primordial set of components, and the preferred examples of certain components are shown for illustrative purposes, to illustrate some of the higher levels of design engineering of said inventive concepts.

FIG. 1 shows a perspective front view from the top and right side, of a preferred embodiment of the Data Gathering Platform, with a detachable and alignable handle (17).

FIG. 2 shows a perspective front view from the right side thereof.

FIG. 3 shows a perspective front view from the top and left side thereof.

FIG. 4 shows a perspective left side view from the front thereof.

FIG. 5 shows front view thereof.

FIG. 6 shows a left side view thereof.

FIG. 7 shows a right side view thereof.

FIG. 8 shows a top view thereof.

FIG. 9 shows a bottom view thereof.

FIG. 10 shows a rear view thereof.

FIG. 11 shows a perspective rear view from the top thereof.

FIG. 12 shows a perspective rear view from the bottom right side thereof.

FIG. 13 shows a perspective front view from the top right side thereof, and showing three instruments, a handheld computer (29), a laser measuring device (28), and a camera (30), each in their respective position on the top plate (1).

FIG. 14 shows a perspective rear view from top left side thereof, and showing the three aforementioned instruments (28-30) each in their respective position on the top plate (1).

FIG. 15 shows a perspective front view from the top left side thereof, and showing the three aforementioned instruments (28-30) each in their respective position on the top plate (1).

FIG. 16 shows an exploded front view from the bottom left side thereof, and showing how the clamp (5) for a handheld computer (29), and the two additional mounting screws (shown in place) for two other instruments (28 & 30) that may be affixed to the top plate (1).

FIG. 17 shows and exploded rear view from the bottom left side thereof, and showing how said clamp () and two additional mounting screws are attached.

FIG. 18 shows an exploded perspective top view from the front and left side thereof, and showing with arrows how three instruments, a handheld computer (29), a laser measuring device (28), and a camera (30), each fit onto their optimally designed position on the top plate (1).

FIG. 19 shows an exploded perspective top view from the rear and right side thereof, and showing with arrows how the aforementioned three instruments (28-30) each fit onto their respective position on the top plate (1).

FIG. 20 shows perspective front view from the top and left side of the Data Gathering Platform invention, but with an alternative instrument placement configuration, having the camera (30) located near the front end of the top plate (1), and the handheld computer (29) located near the rear end of the top plate (1).

FIG. 21 shows an exploded perspective front view from the top and right side thereof, and showing said alternative instrument placement configuration with arrows.

FIG. 22 shows an exploded perspective rear view from the top side and with the stationary clamp () removed to not obstruct this view, and showing the positioning of the handle (17) into one of the four handle alignment positions.

FIG. 23 shows a perspective rear view from the top side thereof, and showing said handle (17) in position to be rotated, as shown with the set of arrows, to the desired one of four handle alignment positions.

FIG. 24 shows a perspective rear view from the top side thereof, and showing the handle (17) rotated and set into the desired one of four handle alignment positions.

FIG. 25 shows a perspective front view from the top and right side, of a simple embodiment of the Data Gathering Platform, with a stationary handle (17).

FIG. 26 shows a perspective front view from the top and left side thereof.

FIG. 27 shows a right side view thereof.

FIG. 28 shows a perspective rear view from the bottom right side thereof.

FIG. 29 shows an exploded perspective top view from the front and left side thereof, and showing with arrows how three instruments, a handheld computer (29), a laser measuring device (28), and a camera (30), each fit onto the desired position on the top plate (1).

FIG. 30 shows an exploded perspective front view from the top and right side thereof, and showing an alternative instrument placement configuration with arrows.

FIG. 31 shows a perspective front view from the bottom and right side of a modified preferred embodiment of the Date Gathering Platform, and with the detachable handle (17) removed.

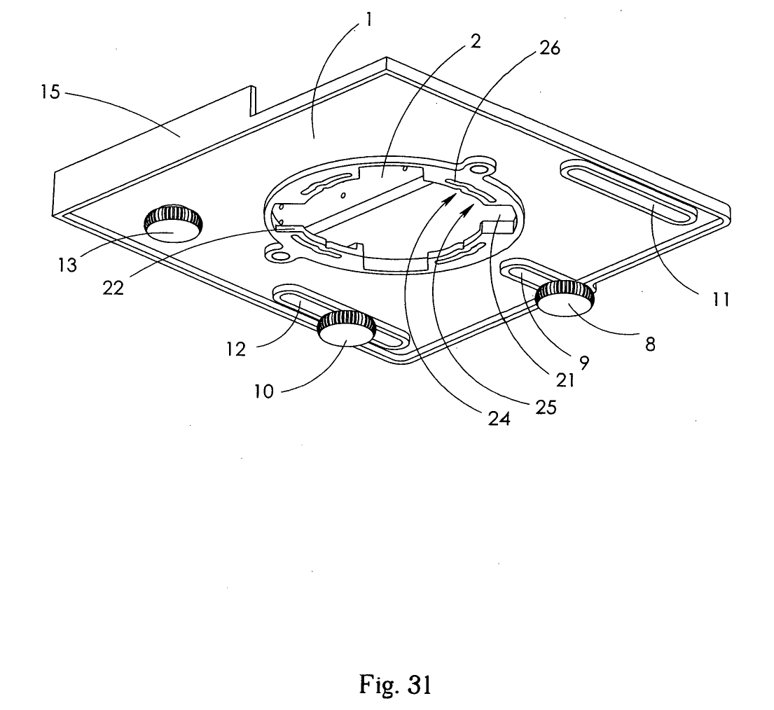

FIG. 32 shows a perspective rear view from the bottom and left side thereof.

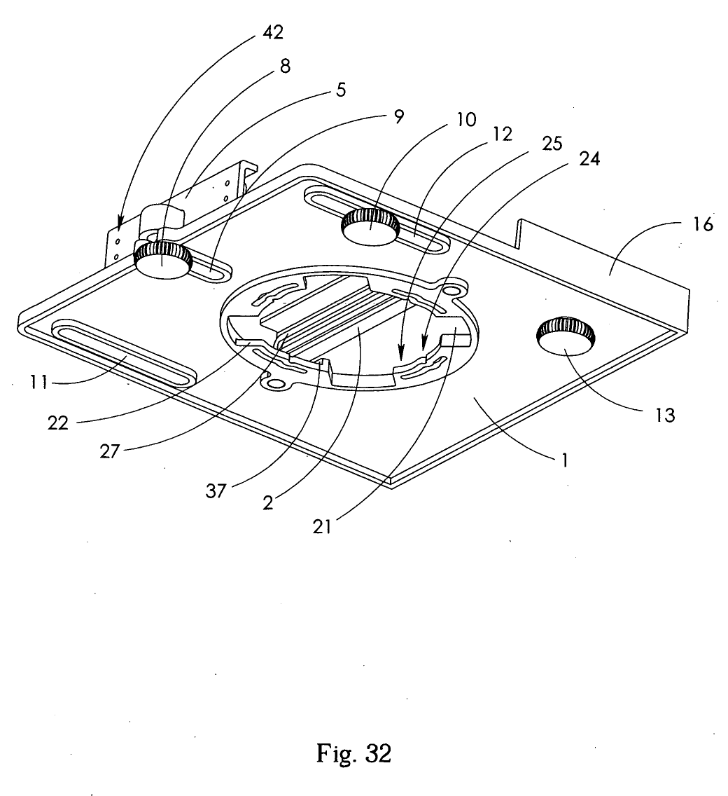

FIG. 33 shows a perspective front view from the top and left side thereof, and showing the three instruments (28-30) in the desired positions on the top plate (1).

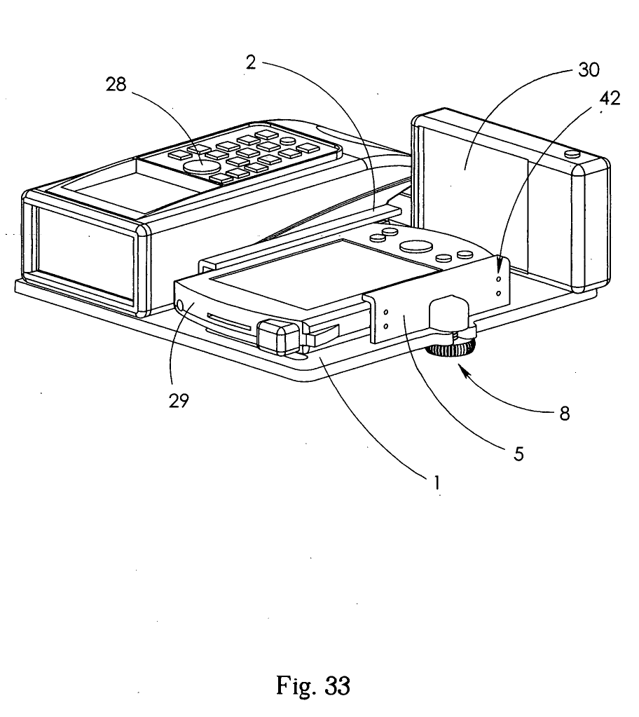

FIG. 34 shows a perspective front view from the top and left side thereof, and showing the three instruments (28-30) in an alternative position on the top plate (1).

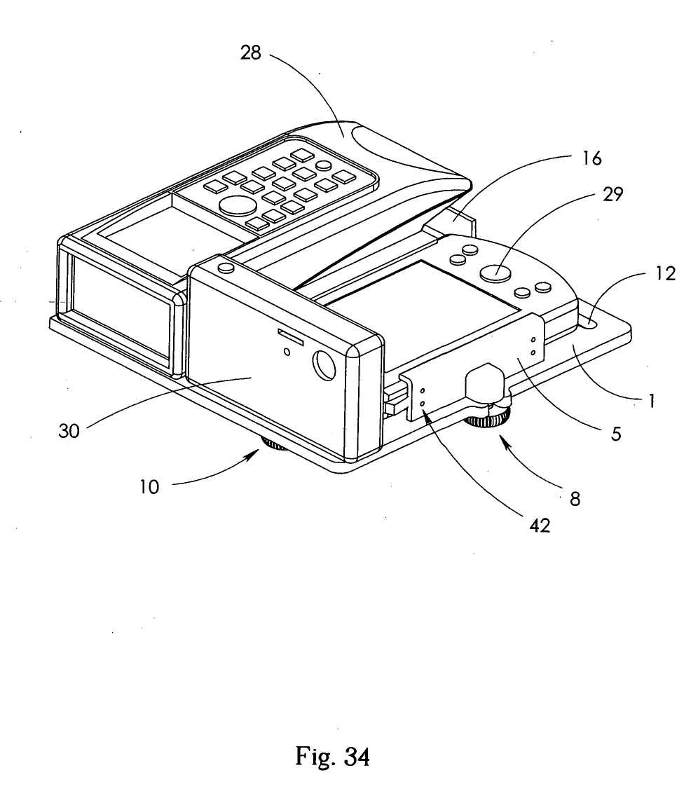

FIG. 35 shows a perspective front view from the top and left side of a modified simple embodiment of the Data Gathering Platform with a stationary handle (17), and such that the top plate (1) has VELCRO® patches (38) to matedly hold the three instruments (28-30) to the top plate, said three instruments (28-30) have mates to said VELCRO® patches (38) attached to their bottom surface to allow easy and reliable attaching to the top plate (1).

FIG. 36 shows a perspective front view from the top and left side of another modified preferred embodiment of the Data Gathering Platform with a detachable handle (17), and such that the top plate (1) has VELCRO® patches (38) to matedly hold the three instruments (28-30) to the top plate, said three instruments (28-30) have mates to said VELCRO® patches (38) attached to their bottom surface to allow easy and reliable attaching to the top plate (1).

FIG. 37 shows a perspective front view from the top and left side of another version of the modified preferred embodiment of the Data Gathering Platform with the detachable handle (17) removed and similar to FIGS. 31-34, and such that the top plate (1) has VELCRO® patches (38) to matedly hold the three instruments (28-30) to the top plate, said three instruments (28-30) have mates to said VELCRO(® patches (38) attached to their bottom surface to allow easy and reliable attaching to the top plate (1).

FIG. 38 shows a perspective front view from the top and left side of another modified simple embodiment of the Data Gathering Platform with a stationary handle (17), and such that the top plate (1) has VELCRO® patches (38) to matedly hold a plurality of remote activators (31) to the top plate, said remote activators (31) have mates to said VELCRO® patches (38) attached to their bottom surface to allow easy and reliable attaching to the top plate (1).

FIG. 39 shows a perspective front view from the top and left side of another modified preferred embodiment of the Data Gathering Platform with a detachable handle (17), and such that the top plate (1) has VELCRO® patches (38) to matedly hold a plurality of remote activators (31) to the top plate, said remote activators (31) have mates to said VELCRO® patches (38) attached to their bottom surface to allow easy and reliable attaching to the top plate (1).

FIG. 40 shows a perspective front view from the top and left side of another version of the modified preferred embodiment of the Data Gathering Platform with the detachable handle (17) removed and similar to FIG. 37, and such that the top plate (1) has VELCRO® patches (38) to matedly hold a plurality of remote activators (31) to the top plate, said remote activators (31) have mates to said VELCRO® patches (38) attached to their bottom surface to allow easy and reliable attaching to the top plate (1).

FIG. 41 shows a perspective front view from the top and left side of another version of the modified preferred embodiment of the Data Gathering Platform with the detachable handle (17) removed and somewhat similar to FIGS. 31 and 32, and such that the top plate (1) has a T-style stationary clamp (2) and two adjustable clamps (5), and may be used to easily and reliably hold a pair of remote activators (31), as shown in FIG. 56.

FIG. 42 shows a perspective front view from the bottom and left side of an embodiment of the Data Gathering Platform with a hinged handle (17) in the closed position. This embodiment with the hinged handle (17), as shown in FIGS. 42 and 43, may be used with the Data Gathering Platform to hold remote activators, or the set of instruments itemized above, the measuring device (28), the handheld computer (29), and the camera (30).

FIG. 43 shows a perspective front view of from the bottom and left side of the embodiment of the Data Gathering Platform, but with a hinged handle (17) in the butterfly open position, and showing details of the hinge base plate (43), the hinge (45), and the two hinge pins (44).

FIG. 44 shows an exploded perspective front view from the bottom and front side of an embodiment of the Data Gathering Platform with a simple detachable handle (17) shown in the off position, and such that a tripod (41) may be screwed into a screw fitting on one of the instruments (28, 29, 30) or devices thereon, thereby sandwiching the top plate (1) between said instrument (28, 29, 30) and the tripod (41), as shown in the present Figure. A tripod (41) may alternatively be screwed into the top plate (1) with a nut or the like, fastening the tripod screw that would thereby protrude to the top surface of the top plate (1).

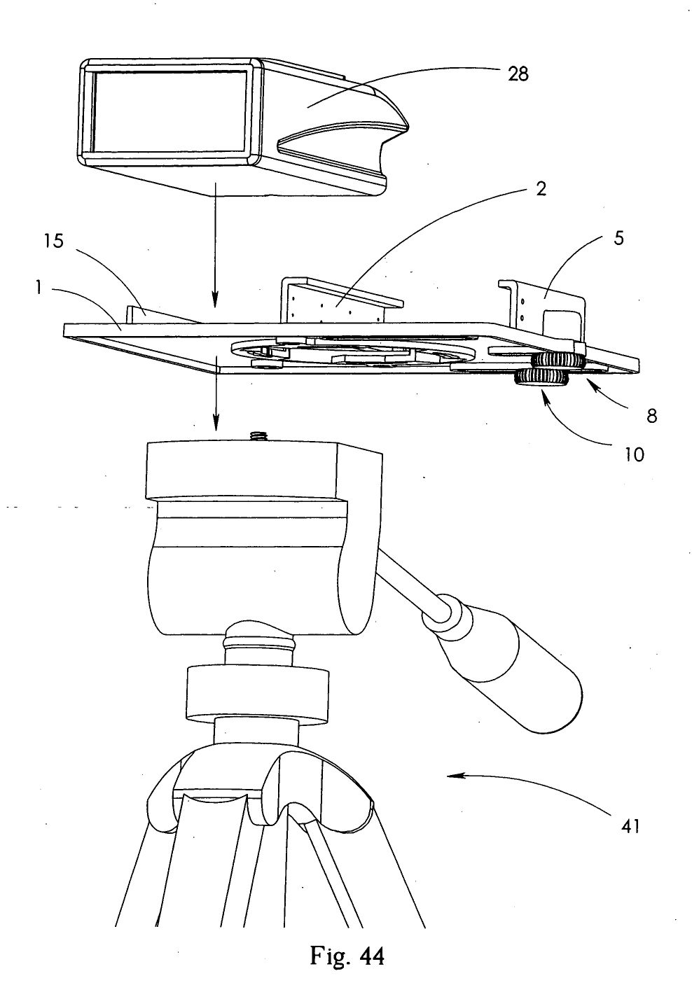

FIG. 45 shows a left side view of a preferred embodiment of the handle (17), showing the aligned connecting slots (19, 20), and the slot dimple (23), that may be shaped like a half-cylinder, as in the present example, or may alternatively be a half sphere or ellipsoid, or the like.

FIG. 46 shows an exploded perspective bottom view from the front of a preferred embodiment of the adjustable clamp (5), and showing how the clamp screw insert (7) may be fit into the clamp screw housing (6), and how the adjustable clamp screw (10) would then fit into the mounted clamp screw insert (7).

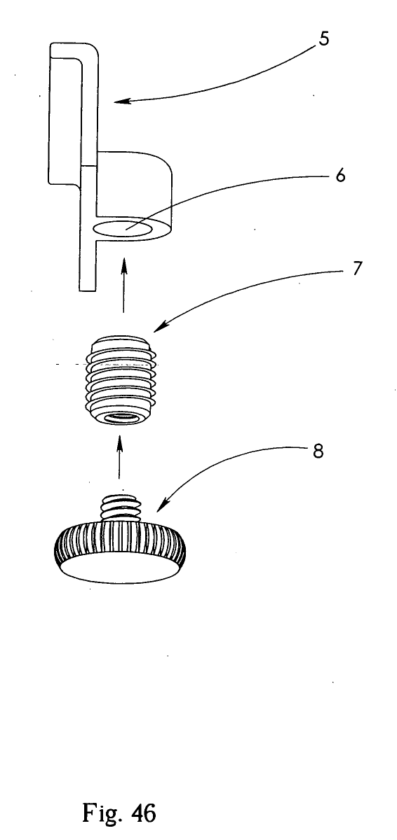

FIG. 47 shows a perspective top view from the front and left side, of the multi-functional hybrid embodiment of the Data Gathering Platform, and with the multi-function hybrid electronic tool effectively built onto the top plate (1), and with a hinged handle (17) shown in the butterfly open position.

FIG. 48 shows a perspective bottom view from the rear and right side, of the multi-functional hybrid embodiment of the Data Gathering Platform, and with the multi-function hybrid electronic tool effectively built onto the top plate (1), and with a hinged handle (17) shown in the closed position.

FIG. 49 shows a perspective top view front and left side, of the multi-functional hybrid embodiment of the Data Gathering Platform, and with the multi-function hybrid electronic tool effectively built onto the top plate (1), and with a permanently affixed handle (17), and showing the touch sensitive computer screen, i.e., the computer (29) on the top surface and showing a trigger guard (46) with two activation buttons (47,48), one measurement activation button (47) for activating the measuring instrument (28), and a camera activation button (48) for activating the camera (30).

FIG. 50 shows a front view of the Data Gathering Platform with a handle (17) affixed to the tripod (41), and with the various instruments and devices (28, 29, 30) attached to the top plate (1).

FIG. 51 shows a right side view of the Data Gathering Platform with a handle (17) affixed to a tripod (41), and without the various instruments and devices (28, 29, 30) attached to the top plate (1).

FIG. 52 shows a perspective top view from the rear and right side, of the Data Gathering Platform without a handle (17), and said Platform with the various instruments and devices (28, 29, 30) affixed to the top plate (1), said top plate (1) affixed to the tripod (41) by a means shown in FIG. 44.

FIG. 53 shows a left side view of a detachable handle (17) in the closed position, and modified to also be hinged, once it is attached to the top plate (1).

FIG. 54 shows a perspective bottom view from the front and left side of a detachable handle (17) in the open position, and modified to also be hinged, once it is attached to the top plate (1).

FIG. 55 shows an exploded perspective top view of the Data Gathering Platform, from the right side, and showing the assembly of a simple embodiment of the detachable hinged handle (17).

FIG. 56 shows a perspective top view from the front left side of the Data Gathering Platform shown without a handle (17), and adapted to hold two remote activators (31) between the modified T-stationary clamp (2).

FIG. 57 shows a perspective front view from the left side of the Data Gathering Platform shown with a hinged handle (17) that may flip up under the bottom surface of the top plate (1), as shown in FIG. 43, and adapted to hold two remote activators (31) between a modified T-stationary clamp (2).

FIG. 58 shows a perspective top view from the left rear side of a Data Gathering Platform with detachable handle, and holding a digital movie camera (30), said Platform now also functioning as a movie camera stabilizer system.

FIG. 59 shows an exploded perspective top view from the front right side of the Data Gathering Platform with a detachable handle (17) that may be screwed onto or off-of the top plate (1), as illustrated in the drawing figure.

FIG. 60 shows an exploded perspective top view from front right side of an embodiment of the Data Gathering Platform with an alternative handle locking means for the detachable handle (17), and where the handle dimple (23) and the dimple port (24) are shown in alternative positions, and the handle release orifice (32) is utilized.

FIG. 61 shows an exploded perspective top view from the front right side of a modified embodiment of the Data Gathering Platform, where the measuring instrument (28) may be mounted along the side of the top plate (1), and to two mounting supports (51) that securely fit into the desired mounting support slots (52) located on the top plate (1).

FIG. 62 shows a perspective top view from the front right side of the embodiment of the Data Gathering Platform shown in FIG. 61.

### DETAILED DESCRIPTION OF THE INVENTION

A description follows below, of the components of the Data Gathering Platform, and as indicated in the reference numerals shown in the various drawing figures.

The top plate (1) is the platform or top surface of the Data Gathering Platform that effectively holds the measuring or recording devices and related instruments. Typically, and for the primary application for the Data Gathering Platform, the top plate (1) would hold a measuring tool (28), such as a laser or sonic measuring instrument (28), a handheld computer (29) or the like, and a camera (30). In a modified embodiment of the invention, the user may use the top plate (1) to hold and house a set of one or more remote activators (31), for remotely activating such consumer electronic products as a television, a VHS player, a DVD player, a stereo system, a security system, etc., etc. Each of said consumer electronic products may require the use of a separate remote (31), but affixing each remote (31) to the top plate (1) effectively makes the plurality of remotes (31) conveniently available, and less likely to become lost or damaged. The top plate (1) may also be used to hold and house other digital and analog instrumentation, as described below in the specification.

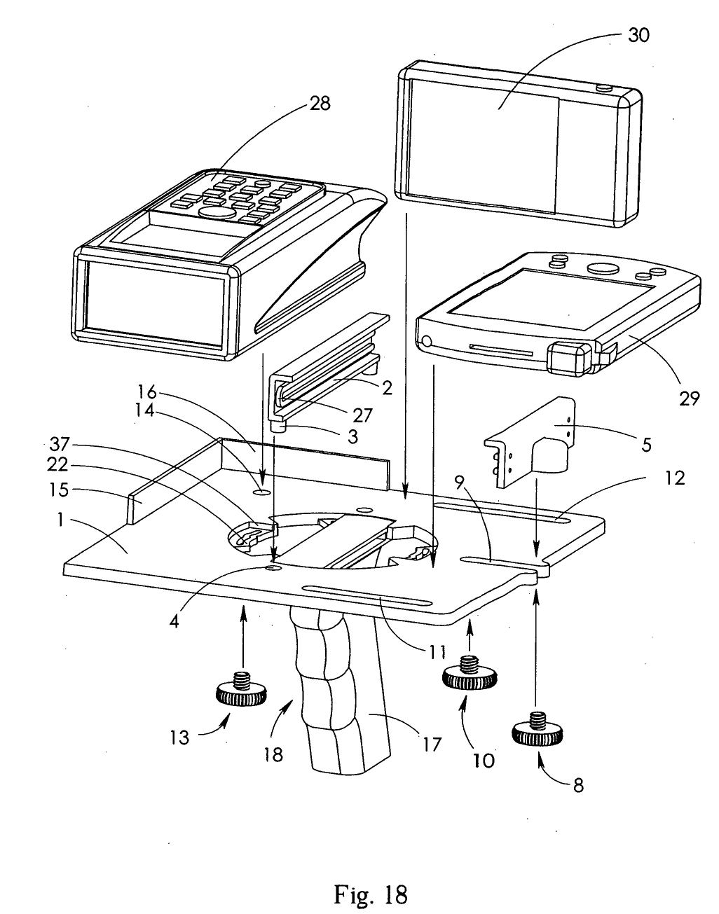

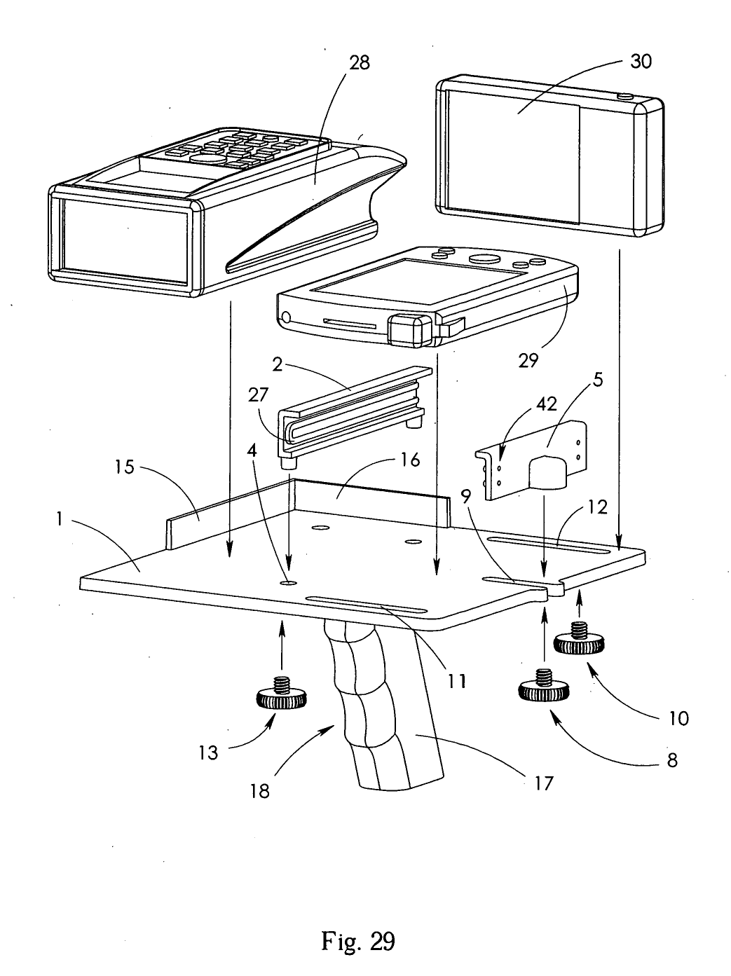

The stationary clamp (2) is a clamp that is affixed to the top surface of the top plate (1) of the Data Gathering Platform. The stationary clamp (2) is typically used to hold one side of a handheld computer (29) in place on the top plate (1) of the Data Gathering Platform. The clamp posts (3) are the posts (3) located on the bottom side of the stationary clamp (2), as shown in FIGS. 18 and 29. The clamp posts (3) matedly fit into their respective clamp post orifices (4), or the like, such as a slot or tapered slot, to effectively hold the stationary clamp (2) firmly into position on the top plate (1). The clamp posts (3) may in some embodiments of the Data Gathering Platform, be glue fitted into the clamp post orifice (4), to more securely affix the stationary clamp (2) to the top plate (1). The stationary clamp (2) typically has two clamp posts (3), that fit into two clamp post orifices (4) located on the top plate (1). Another advantage of the stationary clamp (2) is to provide some additional aligning and to act as an alignment wall for the measuring device (28) that may be stationed adjacent to the side of the stationary clamp (2) opposite the side holding the handheld computer (29).

The adjustable clamp (5) is a clamp that has an adjustable position and is affixed to the top surface of the top plate (1) of the Data Gathering Platform. The adjustable clamp (5) is typically used to hold the side of a handheld computer (29), opposite that side held in place by the stationary clamp (2). The adjustable clamp (5) has an adjustable position and may be affixed along the length of the clamp screw orifice (9), with a clamp screw (8). The adjustable clamp (5) has a clamp screw housing (6) located on its bottom surface. The clamp screw housing (6) may have an internally threaded clamp screw insert (7) therein, so that the clamp screw housing (6) may reliably and matedly receive the threaded portion of a clamp screw (8) extending through the clamp screw orifice (9). The clamp screw insert (7) is typically composed essentially of a hard and durable material, and typically a metal or alloy, such as brass, steel, or aluminum. If a clamp screw insert (7) if not utilized, then the clamp screw housing (6) would be threaded to receive the clamp screw (8).

The camera screw (10) fits through one of the two camera screw orifices (11, 12) located on the top plate (1), and matedly threads into the screw port found on the bottom surface of most all cameras (30). This fitting effectively holds the camera (30) in place on the top surface of the top plate (1). As stated above, there are two camera screw orifices (11, 12). One camera screw orifice (11) is located near the front end of the top plate (1), and the other camera screw orifice (12) is located near the rear end of the top plate (1). This arrangement of the camera screw orifices (11, 12) allows the user of the Data Gathering Platform to affix a camera (30) near either the front end of the top plate (1) or the rear end of the top plate (1), depending upon the user's preference or application. The front camera screw orifice (11) is typically used in a preferred arrangement of the measuring tools and support devices, but for some specialized measuring applications, and for some user's with special needs or preferences, the rear camera screw orifice (12) may be preferred for affixing the camera (30) with the camera screw (10). The camera (30) used may be digital or analog (film), or may be a movie camera (30).

The measuring device screw (13) fits through the measuring device screw orifice (14), located on the top plate (1). The measuring device screw (13) fits through said orifice (14), and matedly fit into the screw port found on the bottom surface of most all optical and laser measuring devices (28), such as the DISTO®, manufactured by LEICA®. The term DISTO® as used throughout this specification is also intended to refer to the DISTO® Plus, and other related devices in the DISTO® series of products. This effectively holds the measuring device (28) onto the top surface of the top plate (1).

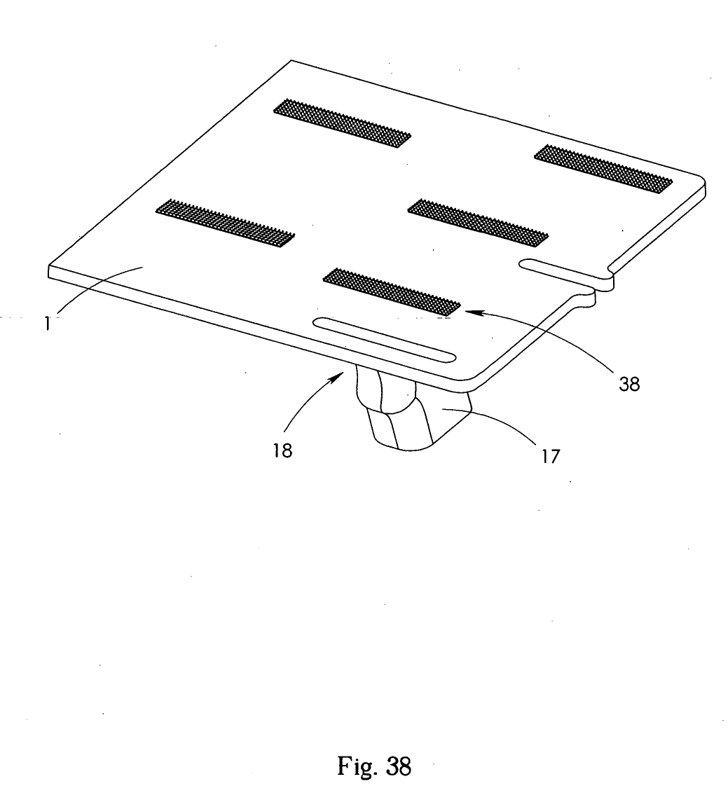

The top plate (1) may have a measuring device stabilizer wall (15) located adjacent to the where a measuring device (28) would be affixed to the top plate (1). The measuring device stabilizer wall (15) would preferably be located along the rear portion of the right side of the top plate's (1) perimeter. A back wall (16) is attached or connected to the measuring device stabilizer wall (15), and located along the right portion of the back side of the top plate's (1) perimeter. The measuring device stabilizer wall (15) has the purpose of stabilizing the location of the measuring device (28), and preventing said device (28) from rotating about the axis of the measuring device mounting screw (13). The back wall (16) further stabilizes the position of the measuring device (28), and adds structural stability and strength to the measuring device stabilizer wall (15), preventing said wall (15) from breaking or collapsing along its perimeter connection to the top plate (1). Some embodiments of the top plate (1) do not have a stabilizer wall (15), or its associated back wall (16), as shown, e.g., in FIGS. 38-43.

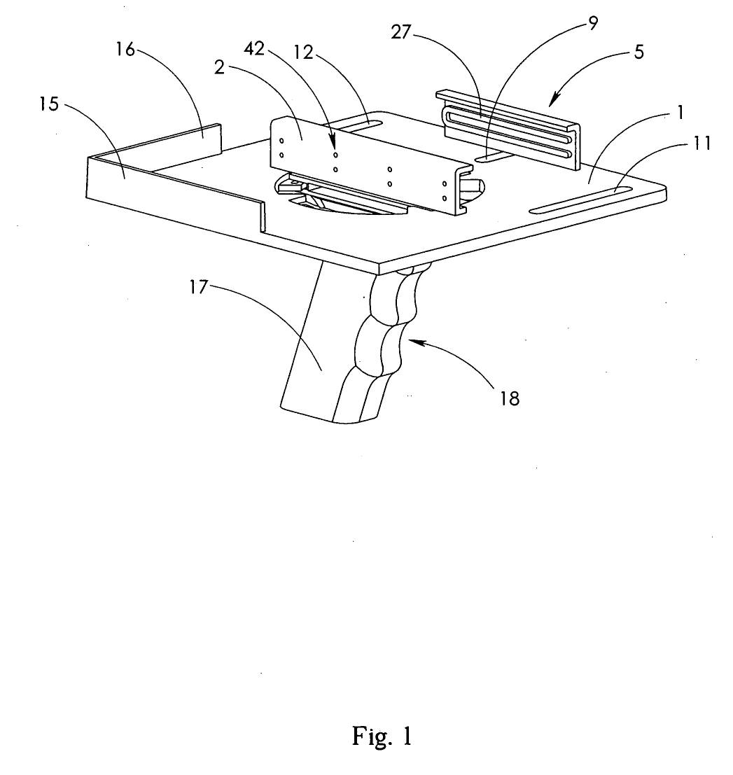

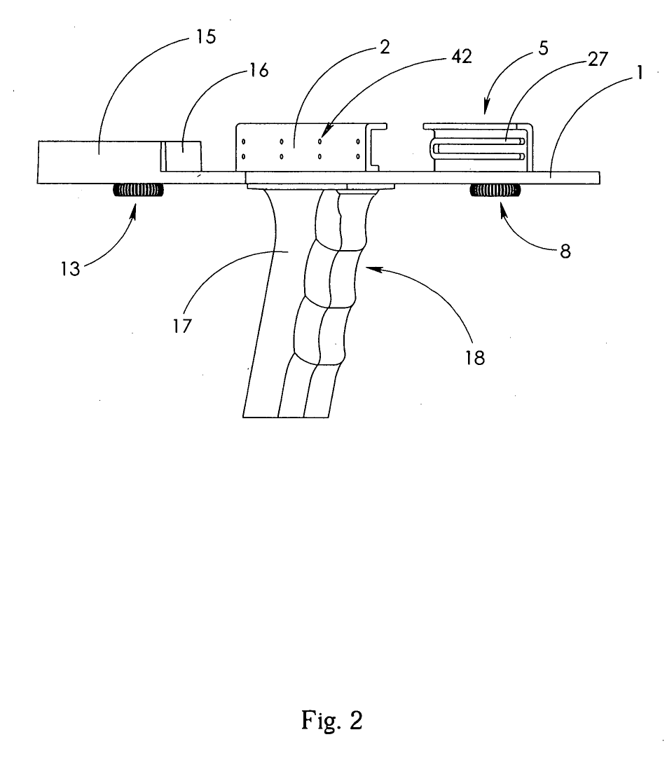

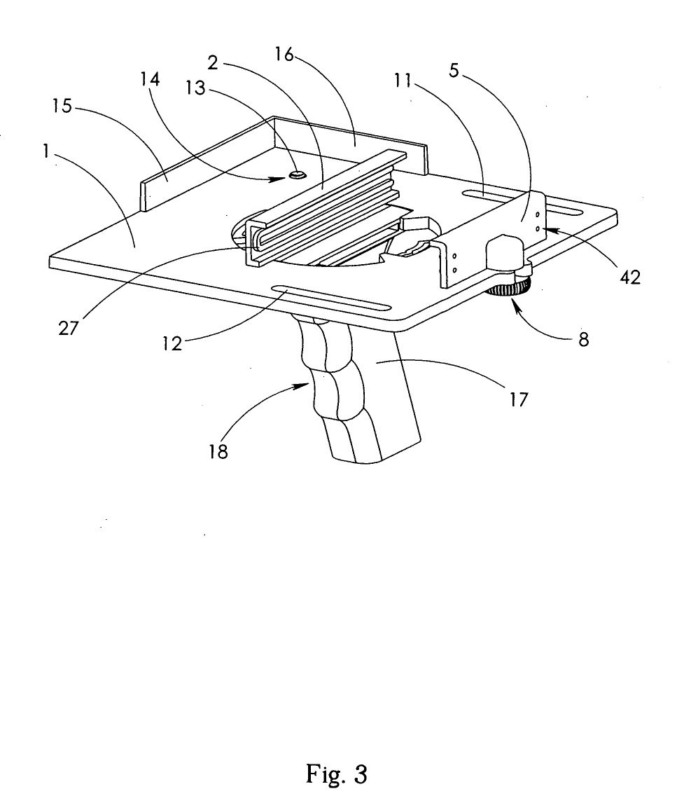

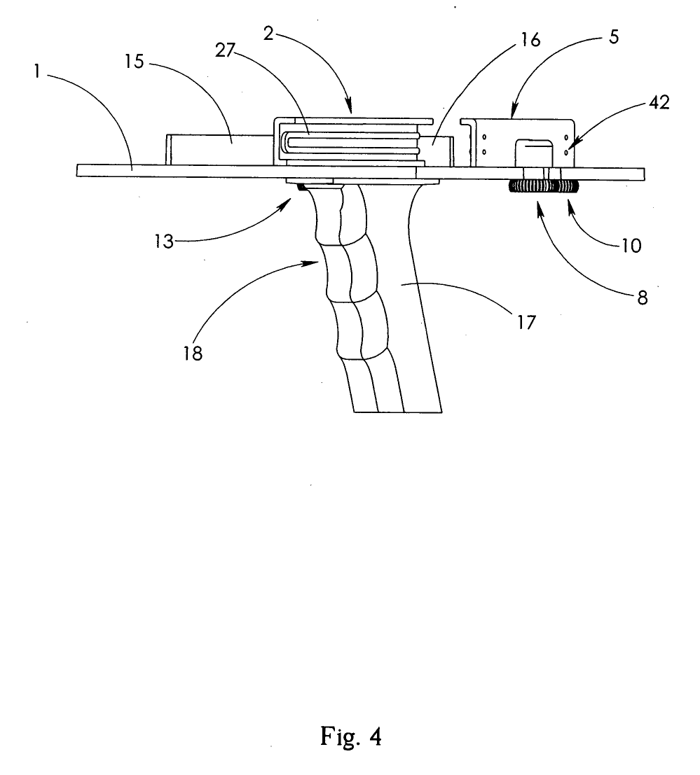

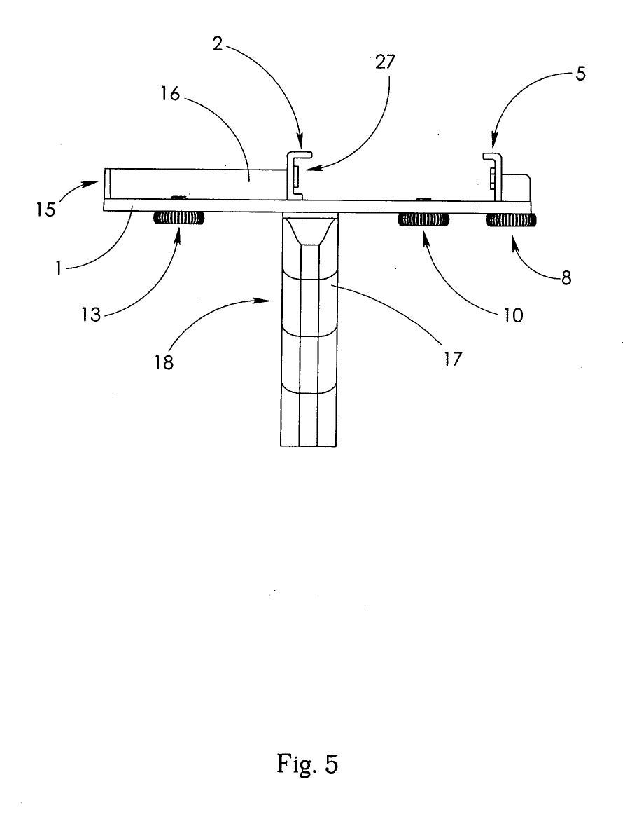

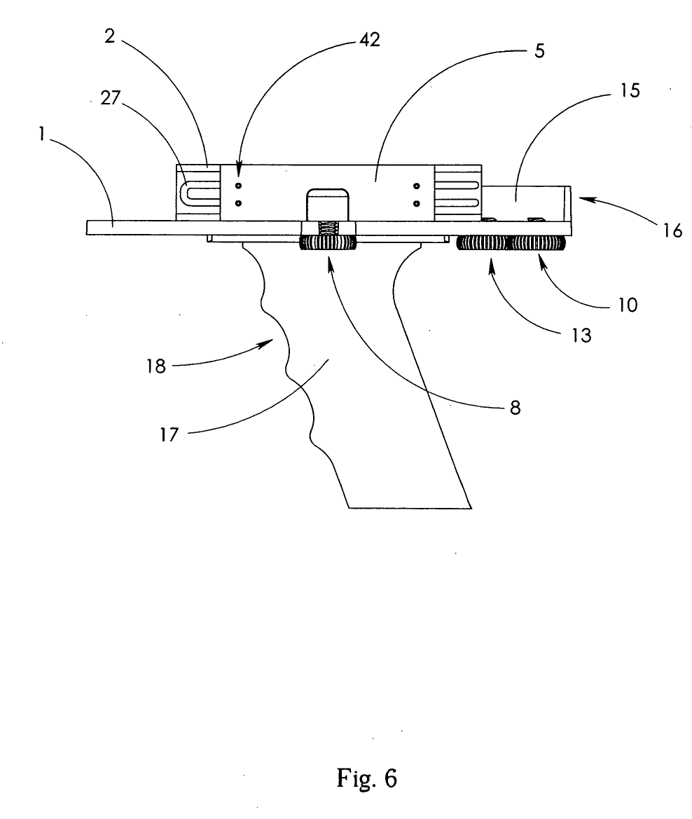

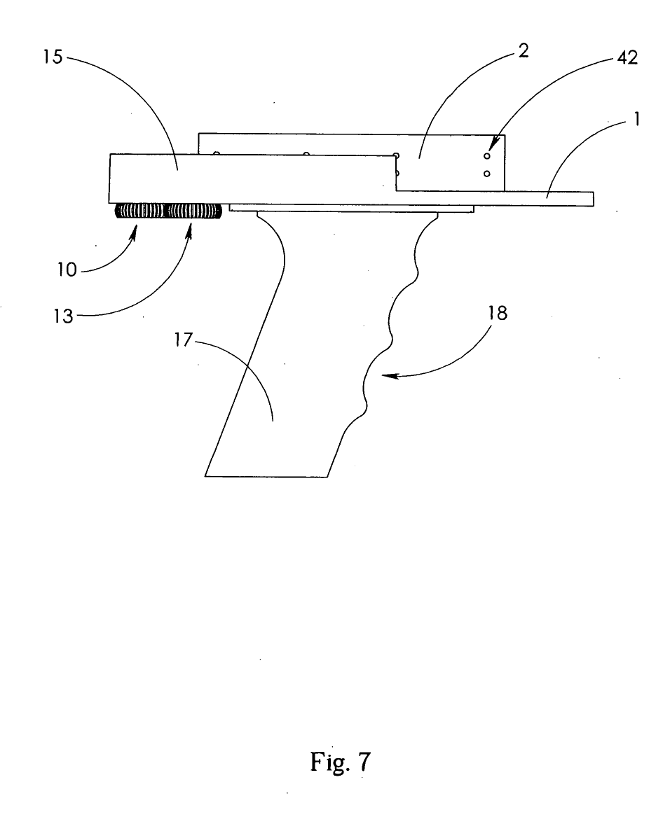

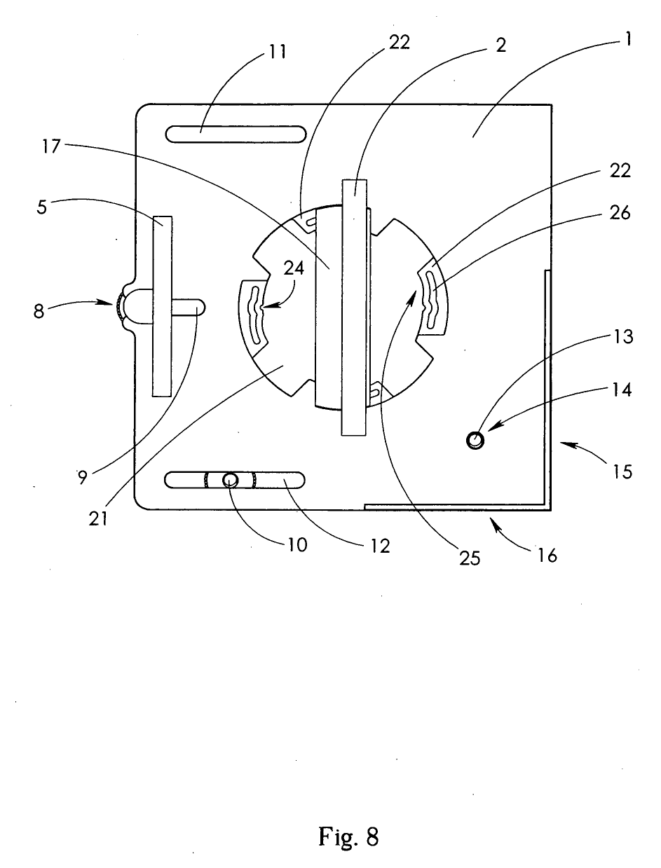

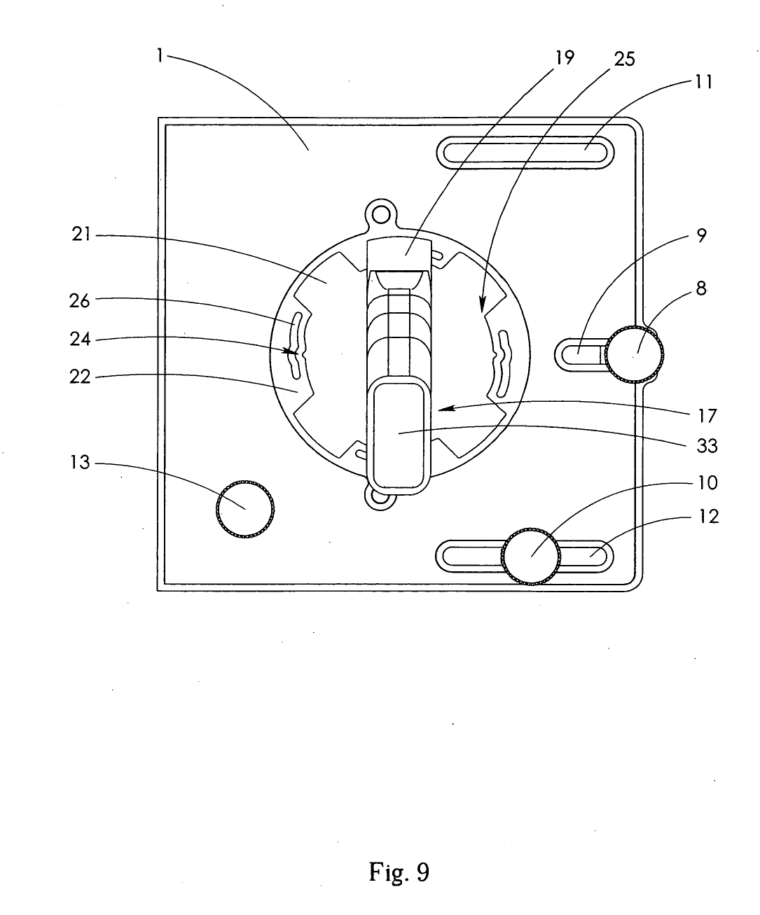

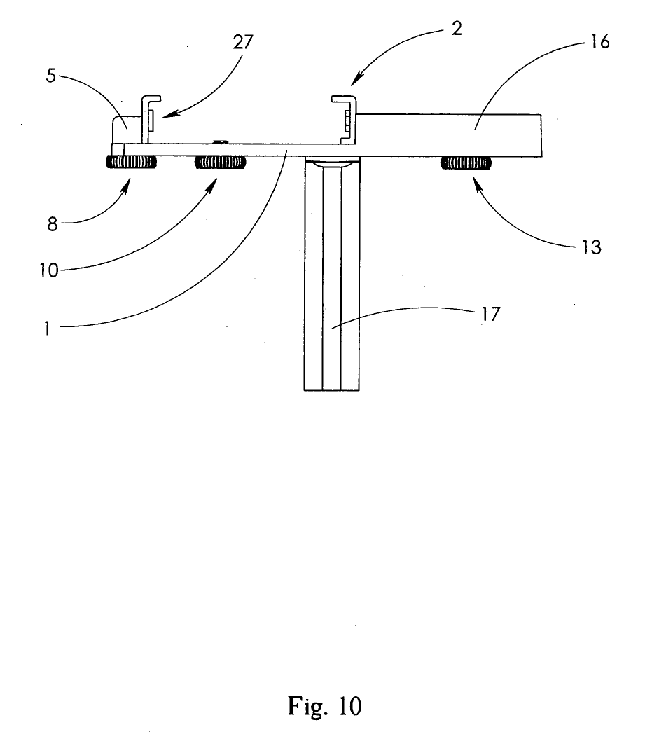

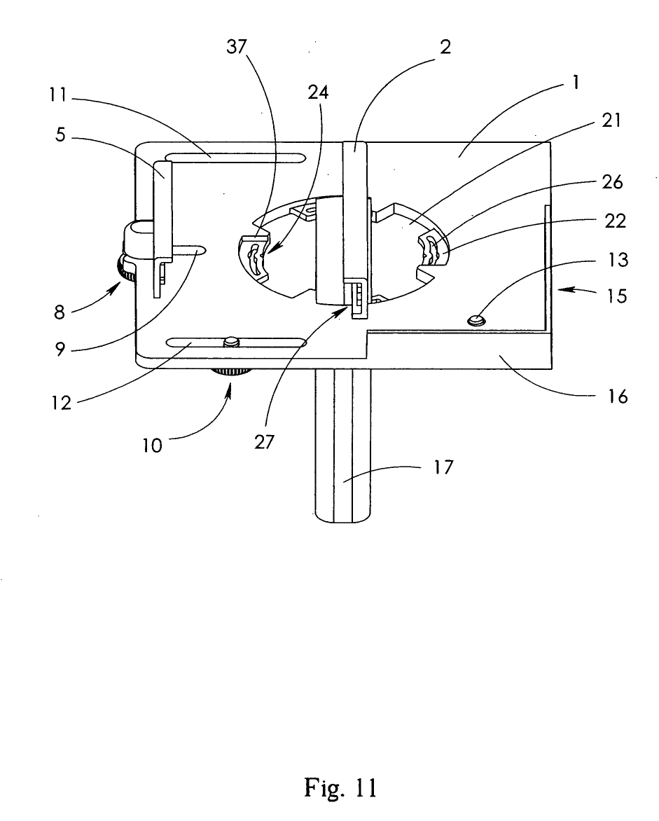

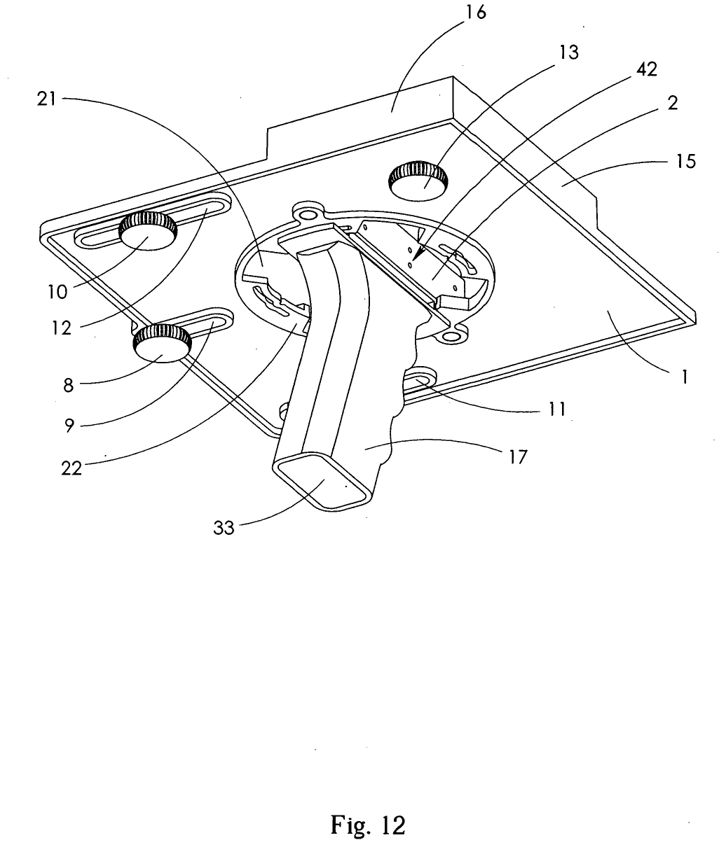

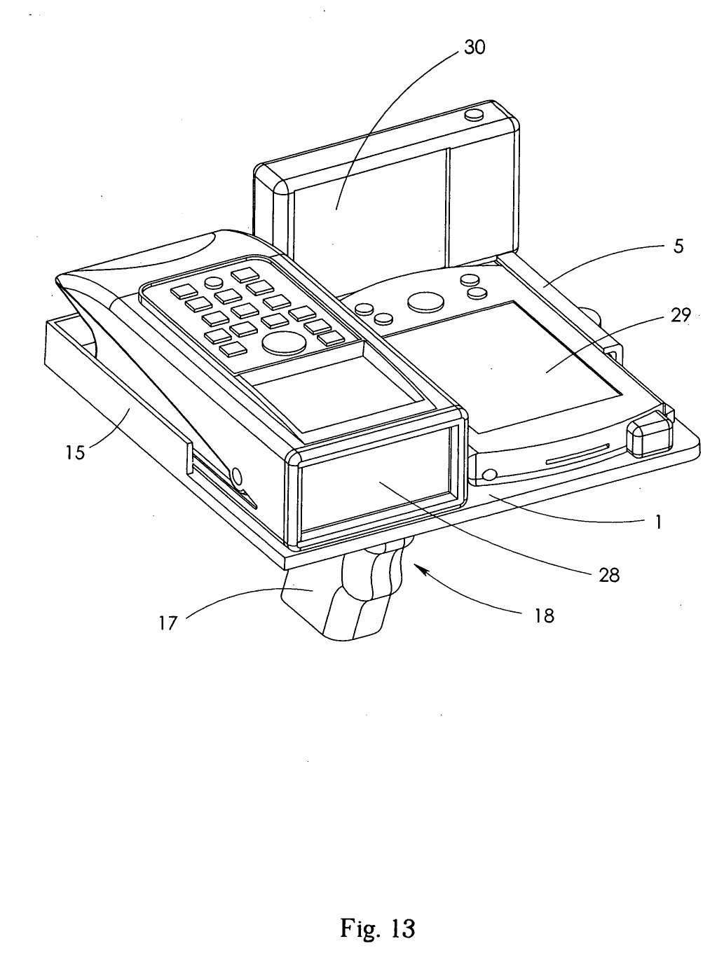

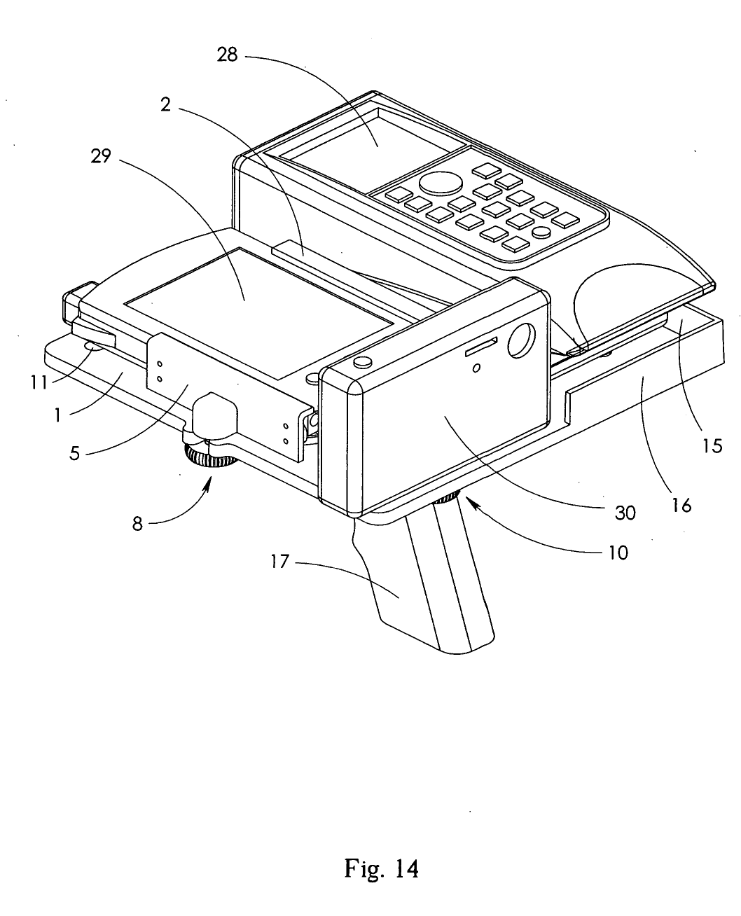

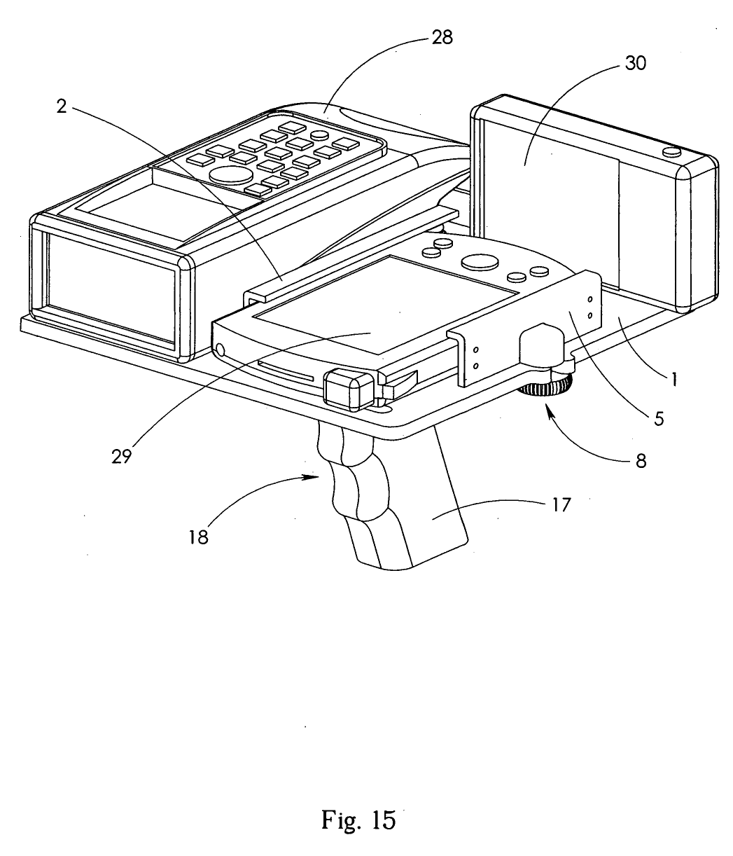

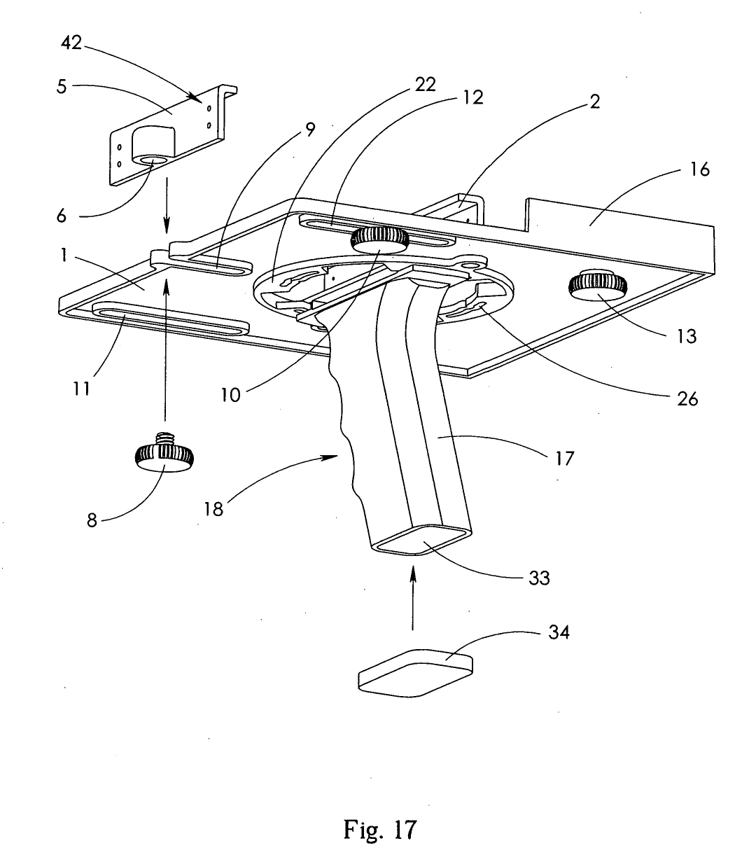

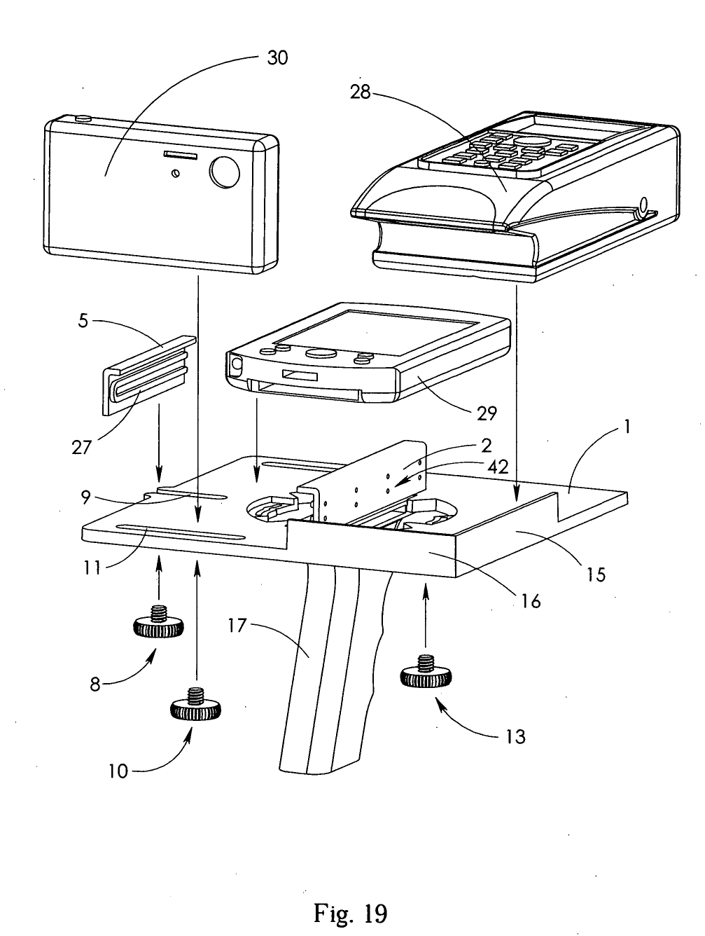

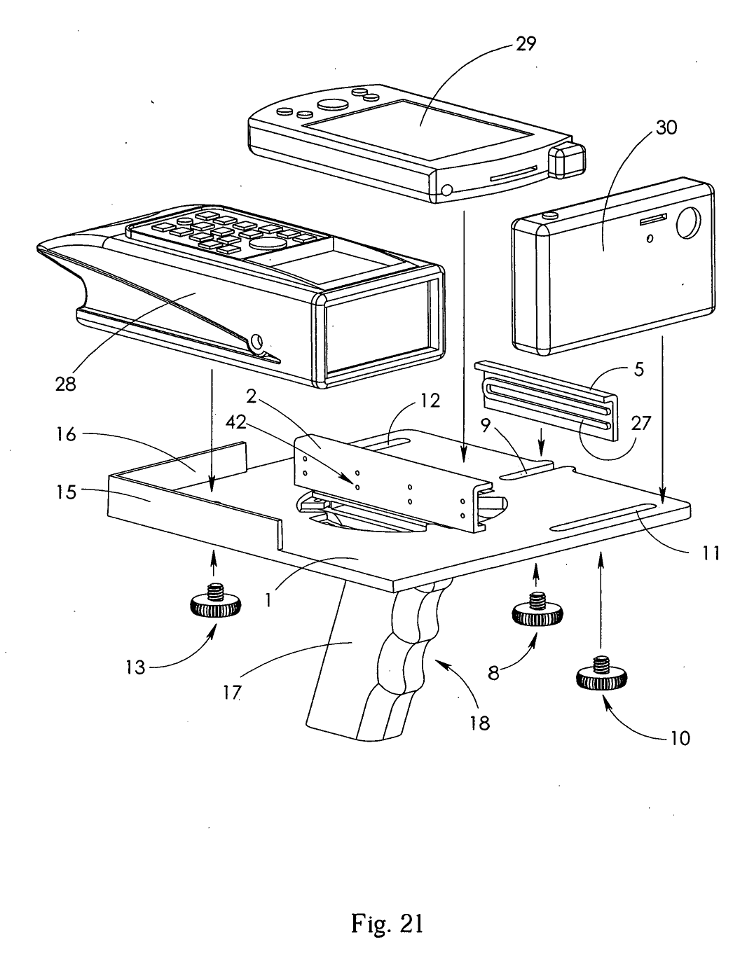

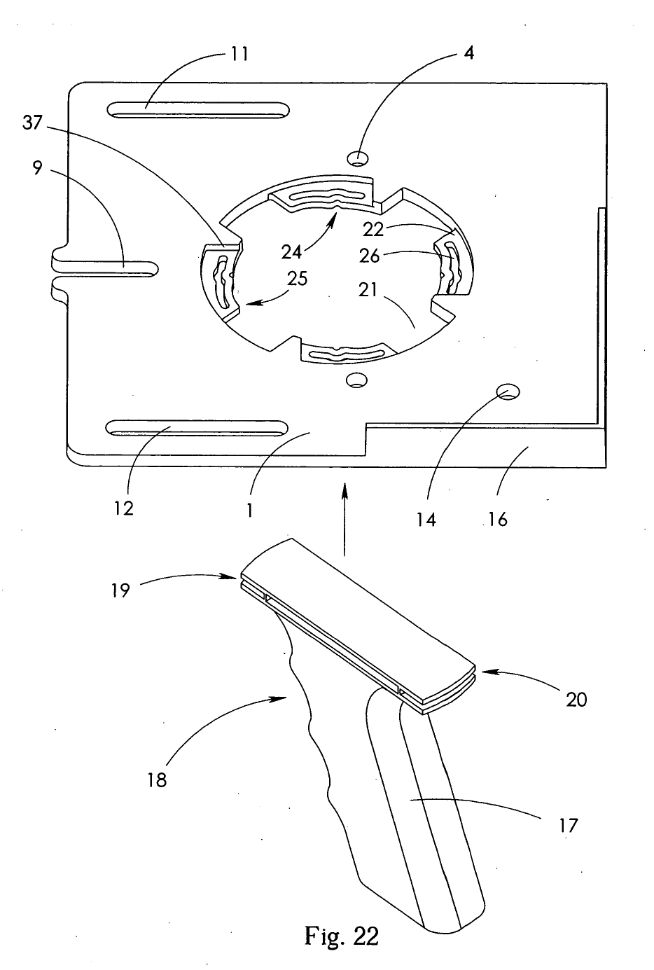

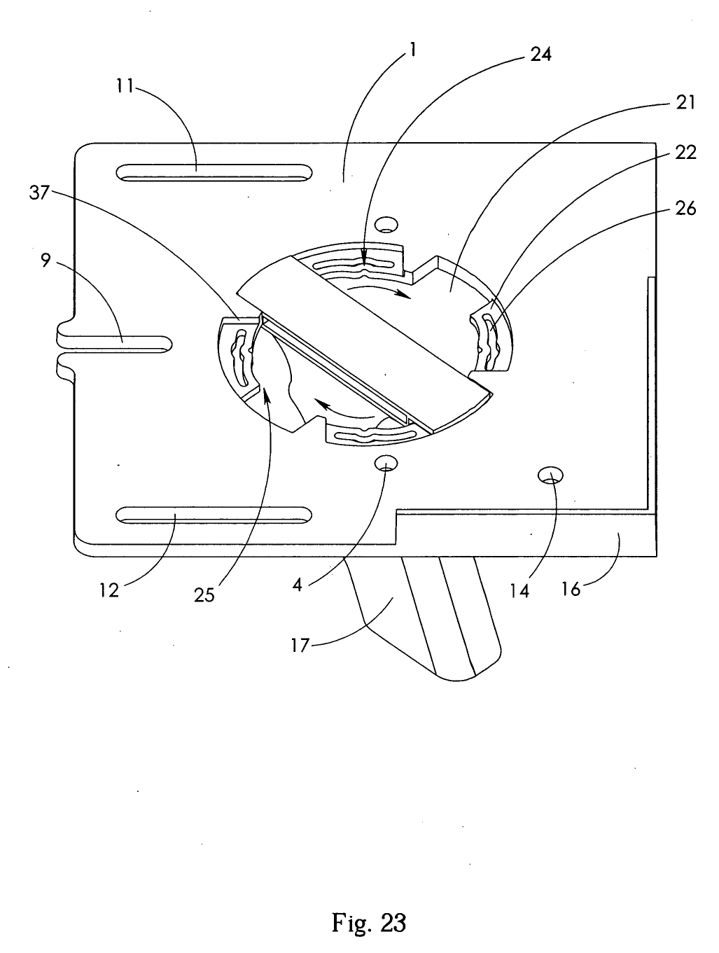

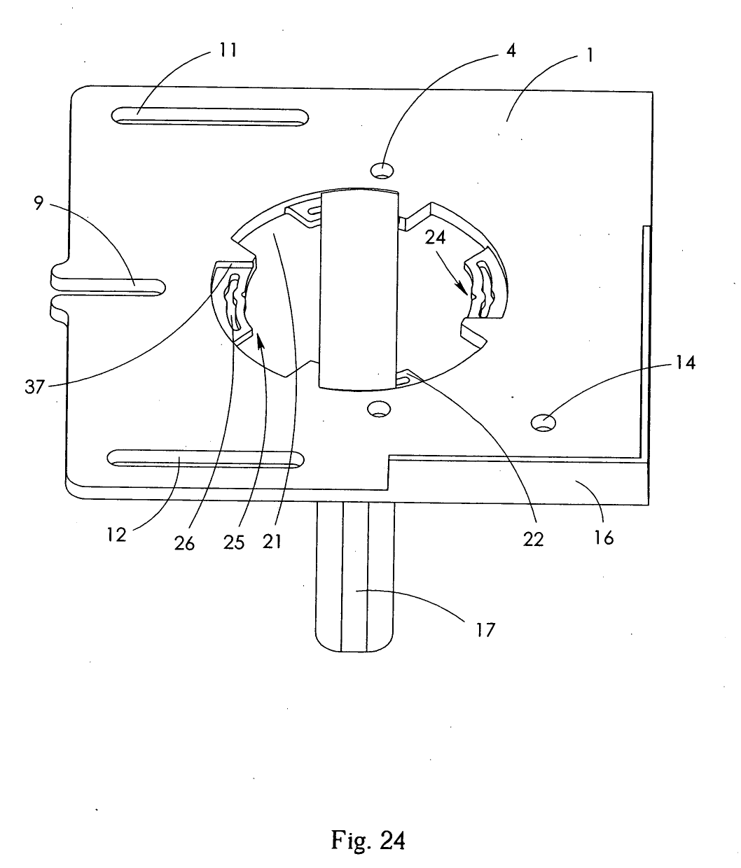

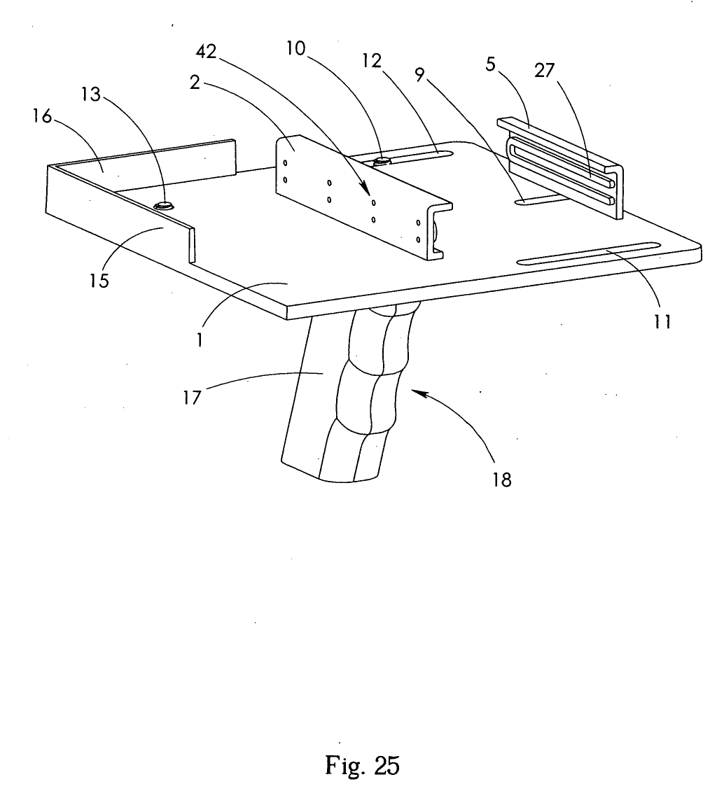

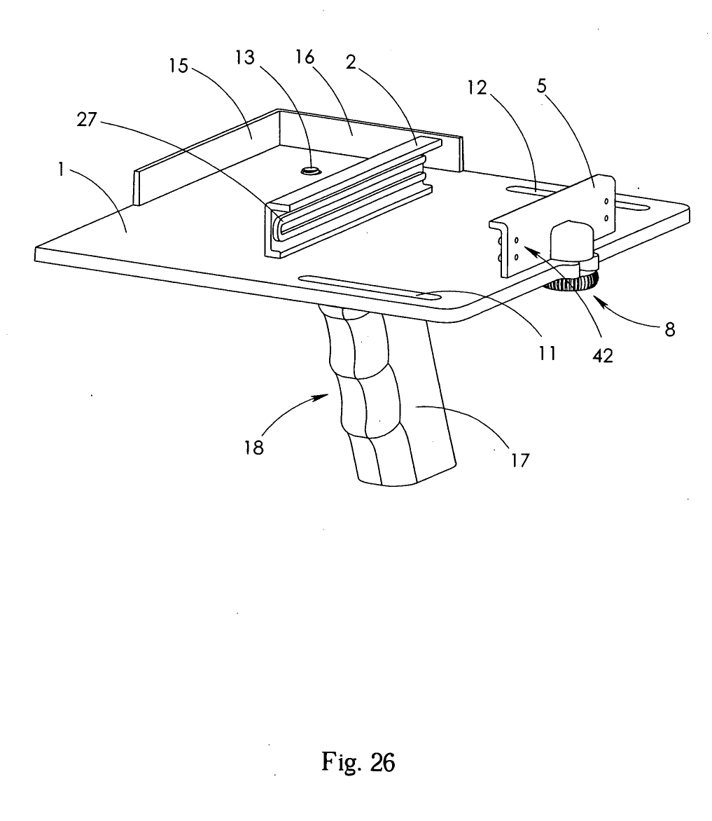

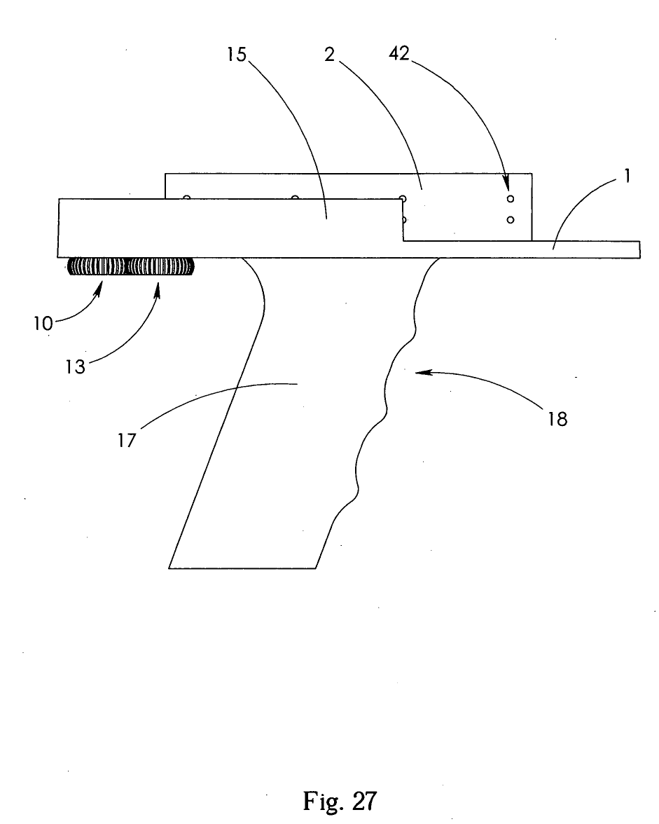

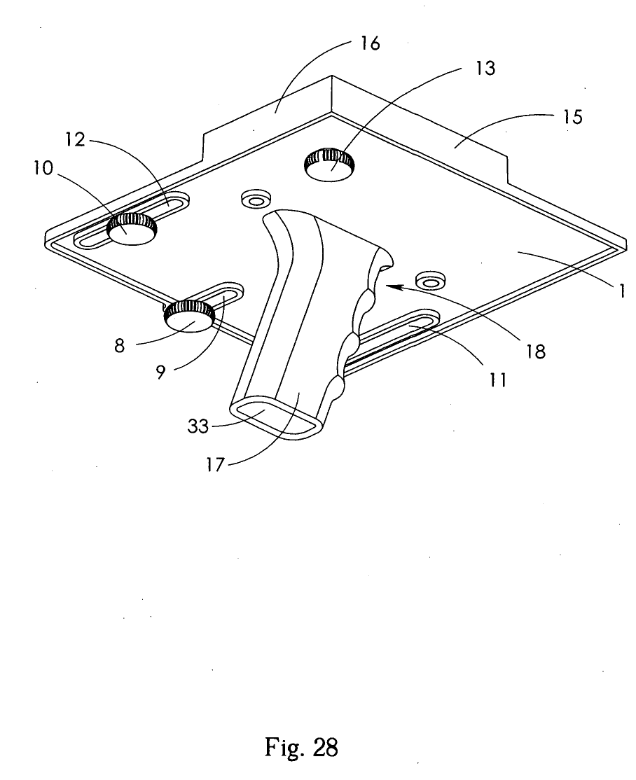

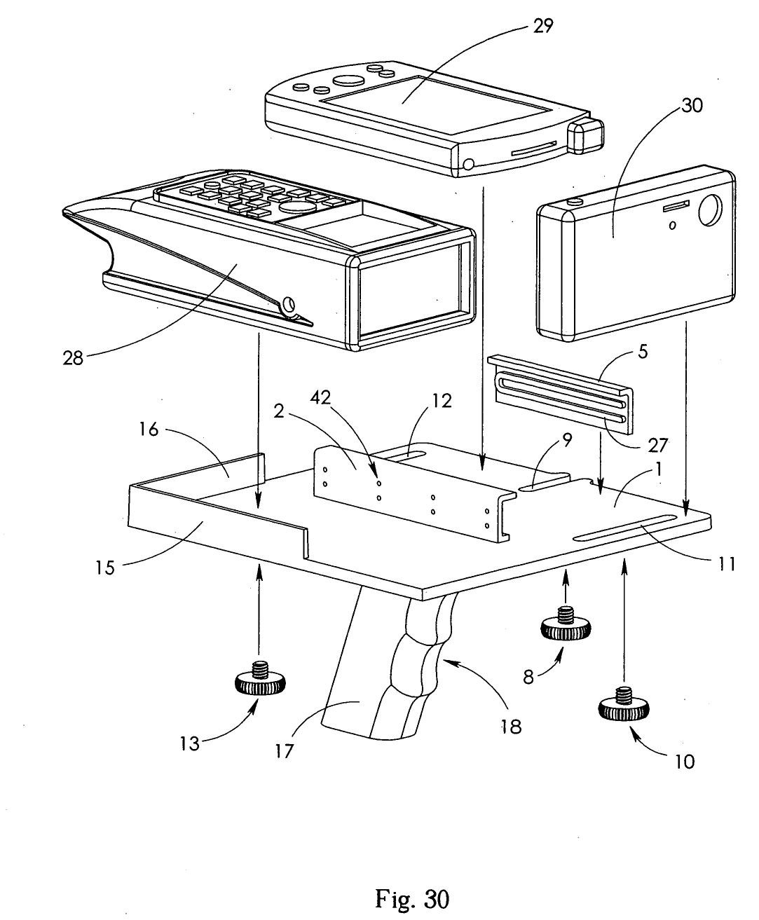

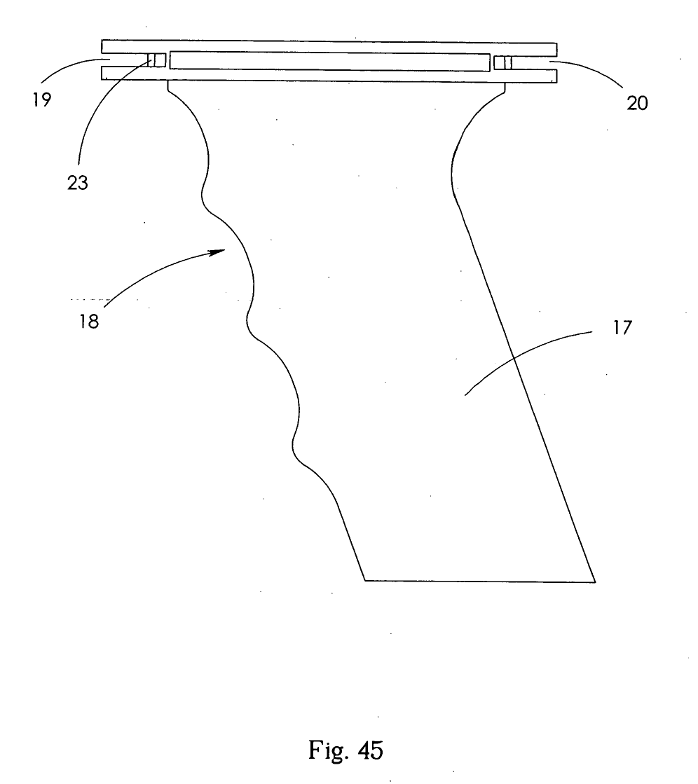

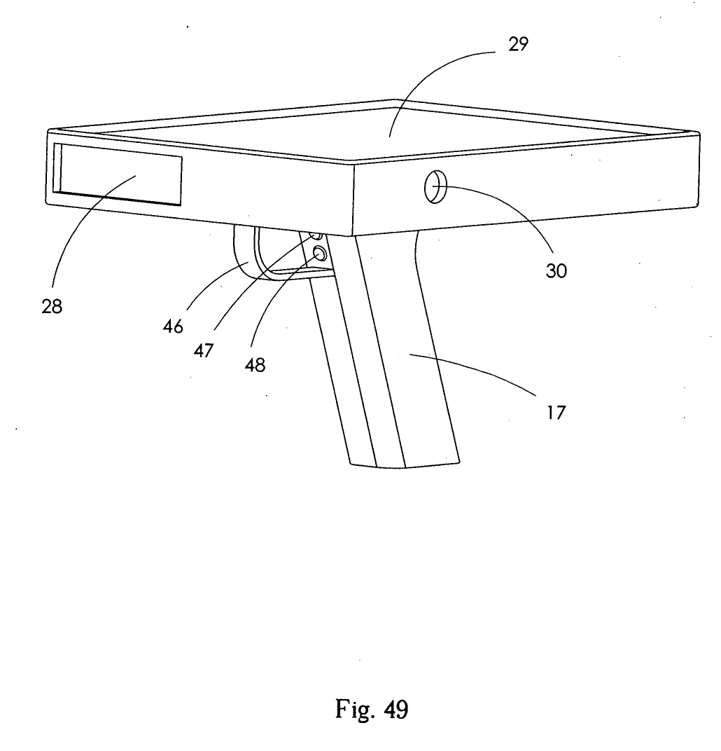

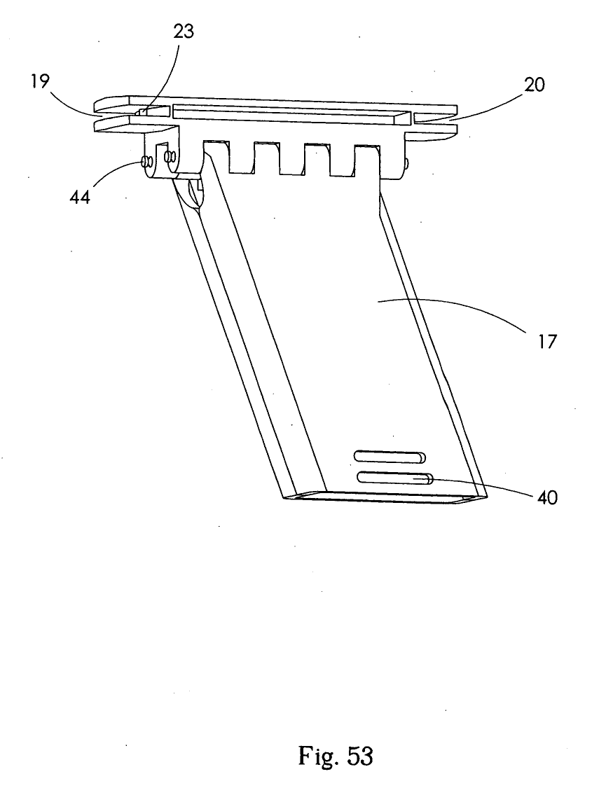

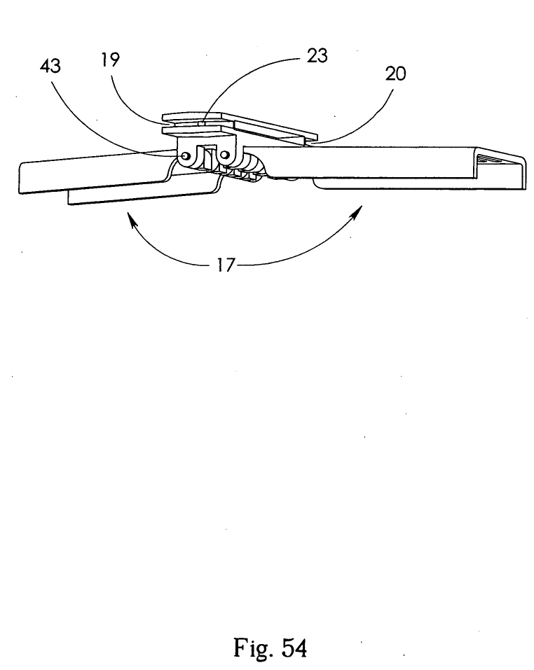

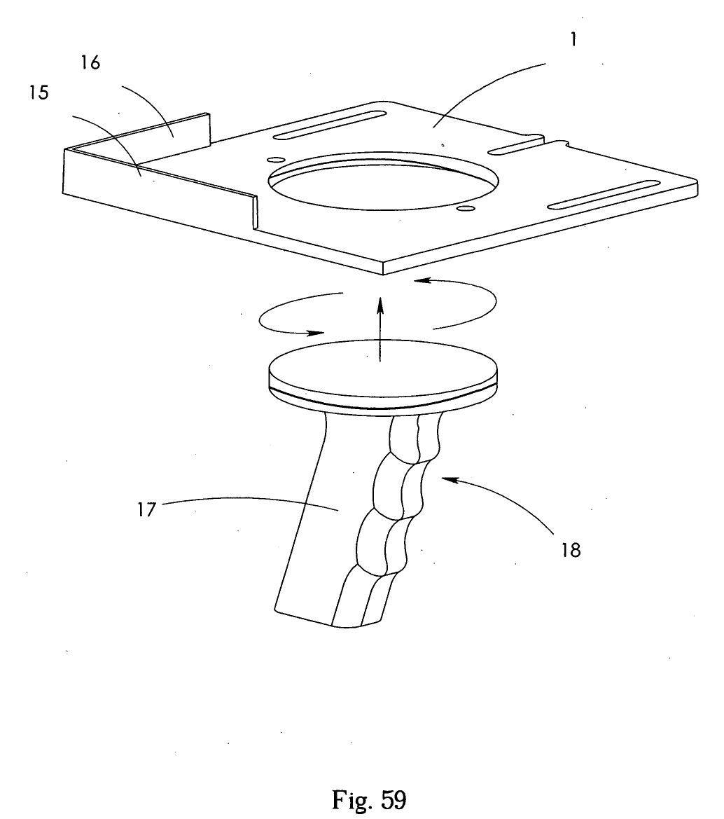

The handle (17) is located at the bottom of the top plate (1), and preferably near the middle of the plate (1). The handle (17) may be permanently affixed to the top plate (1), as is shown in a simple embodiment, and as shown in FIGS. 25-30, 38, 42-43, 48-49, or the handle (17) may be detachable, as is shown in the preferred embodiments, and as shown in FIGS. 1-24, 36, 39, 45, 53-55. The detachable handle (17) may also be alignable in varying positions, and typically four different positions in the preferred embodiments, as shown, e.g., on the top plate in FIG. 8. There are a variety of handle (17) types that may be used, but a pistol grip handle (17) with finger grips (18) is preferred. The preferred pistol grip handle (17) would be inclined at approximately 110 degrees from the front end of the handle (17), as shown in FIGS. 45 and 53, for optimal ergonomic usage. The pistol grip handle (17) would preferably have approximately four finger grips (18) or finger channels, as shown in FIG. 45, to allow the user more control of the handle (17) and the Data Gathering Platform, and also to afford the user a safer grip of the Platform. The detachable handle (17) embodiments may be attached and detached from the top plate (1) in a variety of ways. Such detachable handle (17) embodiments may be screwed into the top plate (1) with one screw or the like protruding from the top of the handle (17), and matedly screwing into a screw port, or the like, to be located on the bottom surface of the top plate (1). Alternatively, a detachable handle (17) may be screwed onto the bottom surface of the top plate (1) with one or more mounting screws or the like. The detachable handle (17) may alternatively have a handle screw (49) at the handle's (17) top surface, so that the handle (17) may be matedly fit into a handle screw port (50) located on the top plate (1), as shown in FIG. 59. Some specialized embodiments of the Data Gathering Platform may use a handle (17) that is unlike a pistol grip, and may be more like a pocket, glove, or port to receive the user's hand or fingers. The preferred embodiments, and variations thereof, of the handle (17) are detachable and alignable, as shown in FIGS. 1-24, and 36, 39, and 53-55. These preferred embodiments of the handle (17) generally have a front connecting slot (19) located at the top of the handle (17), and along the front surface, and has a rear connecting slot (20) located at the top of the handle (17), and along the rear surface, as shown in FIGS. 45 and 53. The connecting slots (19, 20), located at the top of the handle (17), fit into a compatible set of slot access ports (21), located on the bottom surface of the top plate (1), as shown in FIGS. 12, 16-19, 22-24, and 55. Once the connecting slots (19, 20) are fit into the desired compatible set of slot access ports (21), the handle (17) must be turned or rotated about its central axis, to matedly fit a compatible handle connecting rail (22), located on the bottom surface of the top plate (1), into an aligned connecting slot (19, 20), located at the top of the handle (17). The rotation of the handle (17) continues with the slot access ports (21) moving along the handle connecting rail (22), until the side of the access port guides (36) meet the rail stop (37), thereby setting the position of the handle (17). The connecting rail (22) has a width that is essentially parallel to the top plate (1), and the width increases slightly between the beginning of the rail (22) and its terminal end at the rail stop (37). Such an increase in width may be a millimeter or two. The rotation effectively fits the handle (17) onto the top plate (1), thereby uniting the two pieces into a Data Gathering Platform with Detachable Handle. Preferred embodiments of the Data Gathering Platform with Detachable Handle would have a locking mechanism to further secure the handle (17) to the top plate (1). One means of effecting such a locking mechanism is to have one or more slot dimples (23) or the like, located on the top portion of the handle (17) that effectively connect the handle (17) to the bottom of the top plate (1). A good means of achieving this connection is to have a set of dimple ports (24) located on the bottom of the top plate (1) to matedly and snugly receive the slot dimples (23) on the handle (17), thereby effectively locking the handle (17) and the top plate (1) together. To unlock this connection between the handle (17) and the top plate (1), the user need only grasp the top plate (1) with one hand, and the handle (17) with the other hand, and to rotate the handle about its central axis in the opposite direction used to lock the handle (17) in place. A preferred embodiment of the Data Gathering Platform with Detachable Handle would have one slot dimple (23) located in the middle of the back portion of each of the two connecting slots (19, 20), as shown in FIGS. 45, and 53-54. The preferred shape of the slot dimple (23) is ellipsoidal, semi spherical, or semi-cylindrical, and the preferred shape of the dimple port (24) is a shape to compatibly receive the slot dimple (23). A preferred embodiment of the Data Gathering Platform would have a dimple port (24) located along the middle of the innermost edge of each handle connecting rail (22), to matedly receive a slot dimple (23) on the handle (17), as shown in FIGS. 45, and 53-54. The preferred embodiments of the Data Gathering Platform have the handle (17) rotate about its central axis in a clockwise manner, to effectively set and lock the handle (17) onto the top plate (1). Some other embodiments, however, may be designed to require a counterclockwise rotation to affect setting and locking of the handle (17) to the top plate (1), and some other embodiments may locate the slot dimples (23) on the handle connecting rail (22), and to locate the dimple ports (24) on the top portion of the handle (17) that connects to the bottom of the top plate (1), thereby effectively locking the handle (17) and the top plate (1) together in a manner similar to that disclosed above.

In a preferred embodiment of the Data Gathering Platform, each of the top plate's (1) four handle connecting rails (22) has a rail release orifice (26). The purpose of the rail release orifice (26) is to give the connection rail (22) sufficient flexibility to allow the slot dimple (23) to move into and out of the dimple port (24), with a spring-like action, and with appropriate rotational force by the Data Gathering Platform's user. The connecting rail width (25) increases slightly from the beginning of the connecting rail (22) to the location of the dimple port (24), located on the connecting rail (22), so that the handle (17) may be more securely fit onto the top plate (1).

Some embodiments of the Data Gathering Platform may have clamp pads (27) located on the face surface of the stationary clamp (2) and the adjustable clamp (5), and a similar pad material may be located over the surface of the handle (17) to improve the gripping ergonomics. The face surface of the clamps (2, 5) may be flat or concave to accept the instrument more firmly, although a preferred embodiment of the clamps (2, 5) would be a flat face surface with the clamp pads (27) being a strip or set of strips, thereby affecting a quasi-concave effect. The clamp pads (27) are typically an overmold material composed of a polymeric or elastomeric material such as a rubber or neoprene formulation, and may be a large pad covering much of the concave surface of the clamps (2, 5) or much of the surface of the handle (17), or may be a set of smaller clamp pads (27) to approximate the same effect as one larger clamp pad (27). The purpose of the clamp pads (27) is to grip and hold securely in place the device or instrument held between the stationary clamp (2) and the adjustable clamp (5). Said device or instrument held between said clamps (2, 5) is typically a handheld computer (29), a remote activator, or the like. When an overmold material is used to make clamp pads (27), an overmold anchor fit into an anchor port (42) may be used to hold an overmold clamp pad (27) in place on the desired surface. The clamp pads (27) may alternatively in some embodiments, be glued or bonded onto the clamps (2, 5), and their equivalent may in some embodiments, be glued or bonded onto the grip surface of the handle (17).

The measuring device (28) is the modern instrument that may make a length measurement using an optical beam, such as a laser beam, or by means of an acoustical signal or beam, such as sonar or the like. A preferred embodiment for the measuring instrument (28) is a laser measuring instrument (28), such as the DISTO® series of measuring instruments, as manufactured by LEICA®.

The handheld computer (29) is the modern portable and handheld computer instrument (29) that typically has a modified type of WINDOWS® program, such as Windows Mobile TM, and is programmable, much like a personal computer, but is the size of a typical handheld programmable calculator. A preferred embodiment for the handheld computer (29) is the Dell Axim X50v, as manufactured by Dell Computers, Inc., or the HP 4700 series, or alternatively the HP 5550, as manufactured by HEWLETT-PACKARD®. A preferred software program used in the handheld computer (29) for optimal applications in the real property appraisal industry is MOBILE SKETCH TM, as manufactured by Apex Software, Inc.

The camera (30) is the modern instrument that may take and record a plurality of images, either on film or in a memory bank or card. A preferred embodiment for the camera (30) is a digital camera (30), and preferably with a good lens resolution and high pixel resolution. Some applications of the Data Gathering Platform may use an analog or film camera (30) or a movie camera (30).

The remote (31 ) is the remote activator (31 ) that may be used to remotely activate a consumer electronic device or the like, such as a television, VHS, DVD, stereo system, alarm and security system, and other devices or systems.

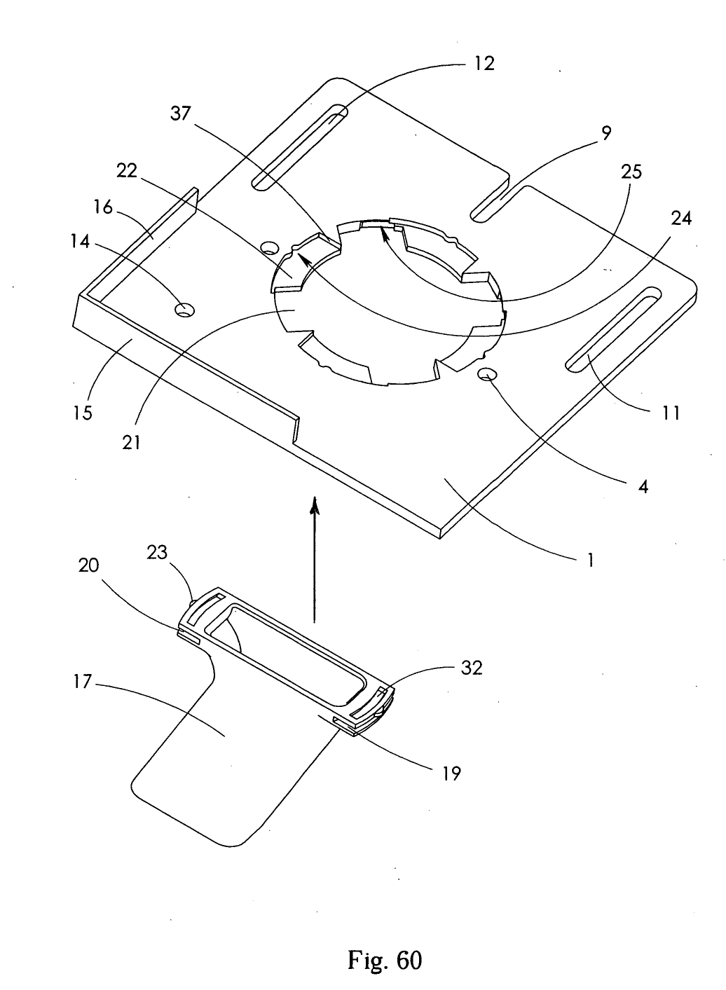

In a modified embodiment of the Data Gathering Platform, as shown in FIG. 60, the top portion of each handle's (17) two connecting slots (19, 20) has a handle release orifice (32) with a slot dimple (23) located on each connecting slot's (19, 20) edge, and such that each said dimple (23) would matedly fit into a dimple port (24) located on the connecting rail (22). The handle release orifice (32) is to provide some flexibility for the dimple (23) to fit into and out of its associated dimple port (24). This embodiment is somewhat similar to the preferred embodiment of the Data Gathering Platform.

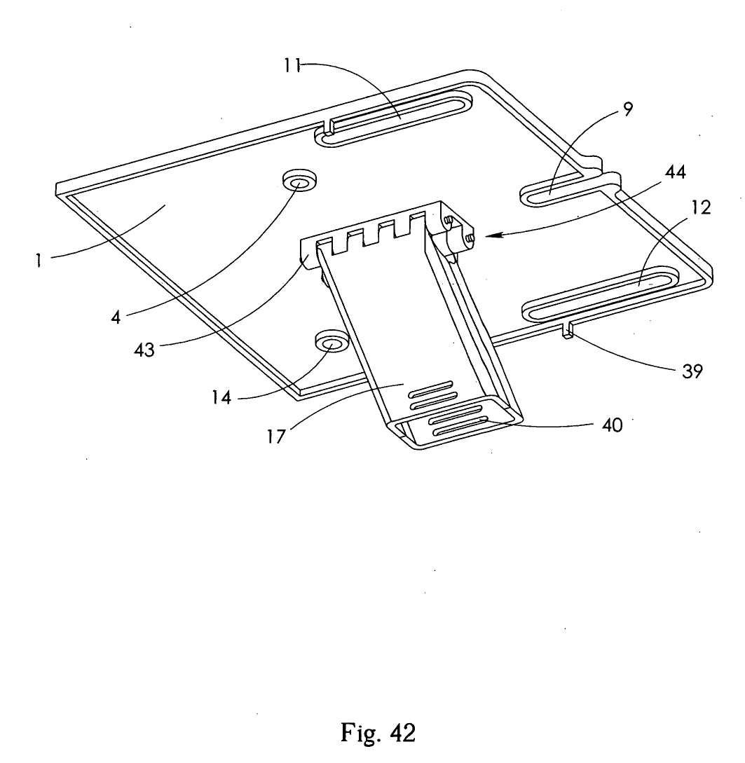

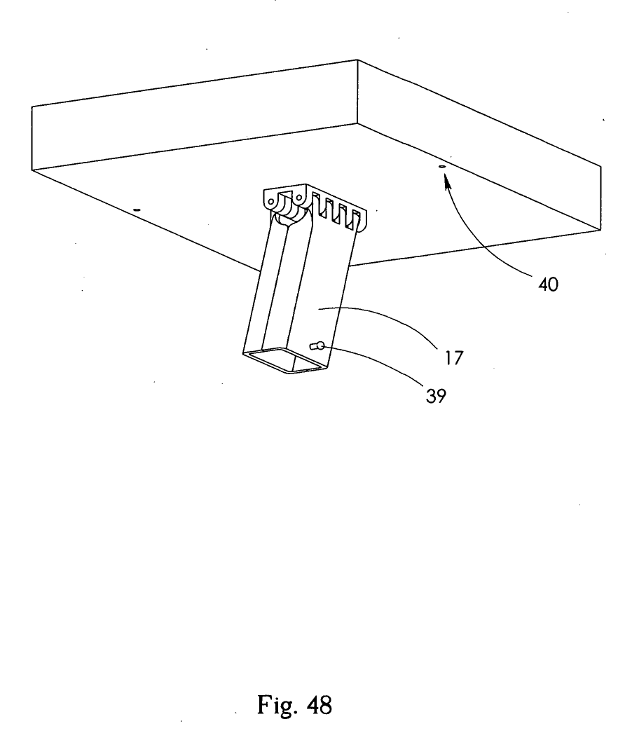

In some modified embodiments of the handle (17), the handle (17) may be hinged such that it may split apart and “butterfly up against the bottom surface of the top plate (1), for easy storage or carrying, and as shown in FIGS. 42-43 and 53-55. Alternatively, the handle dimple port (40) may be located on the handle (17), and the handle dimple would then be located on the bottom of the top plate (1), as shown in FIG. 48, to matedly fit into the handle dimple port (40), when the handle (17) is opened into a “butterfly” position. Such hinged handle (17) embodiments may be stationary or detachable, and may optionally use a handle dimple (39), located on the handle (17), and a handle dimple port (40), located on the bottom surface of the top plate (1), to hold the opened handle (17) in the “butterfly” position on the bottom of the top plate (1). The closed handle (17) may be held in the closed position manually by the user, or it may, e.g., be held together with a set of dimples and dimple ports located so that one or more dimples and their respective dimple ports matedly align together as the two sides of the opened handle (17) is closed and matedly fit and snap together as the two sides of the handle (17) are put in the closed position.

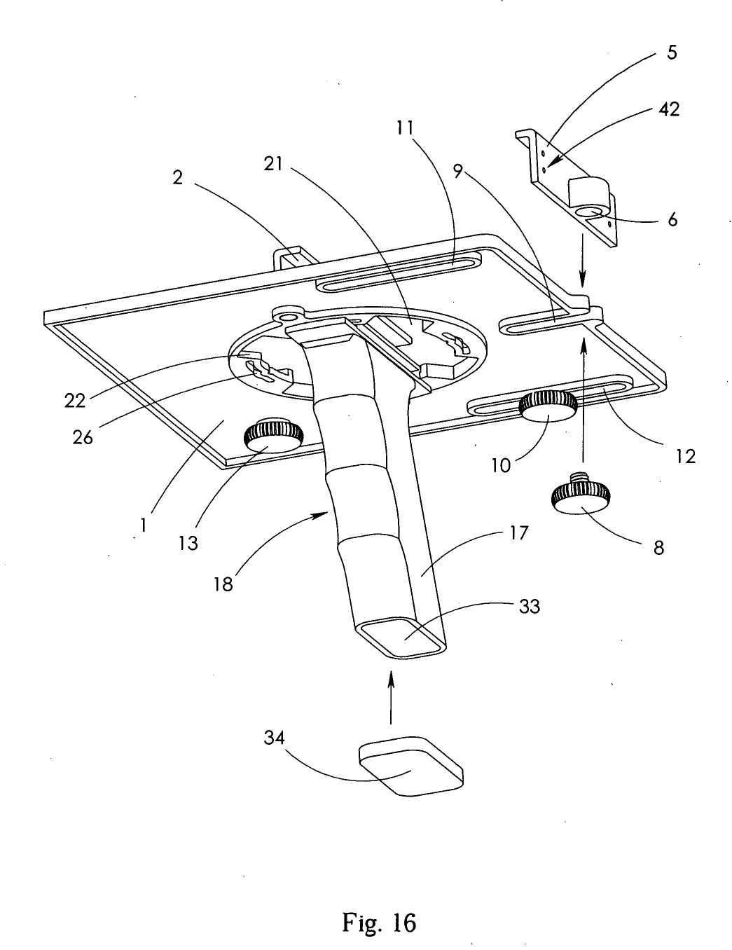

In some modified embodiments of the handle (17), the handle (17) may be hollow or solid and drilled-out to form a handle storage cavity (33). The handle storage cavity (33), allows the user to store supplies, such as replacement batteries, memory chips or a memory stick, wrist straps (35), etc., etc. In such embodiments with the handle storage cavity (33), a handle cap (34) or fitting would be needed to cover the open end(s) of the handle (17), as shown in FIGS. 16, 17, and 20.

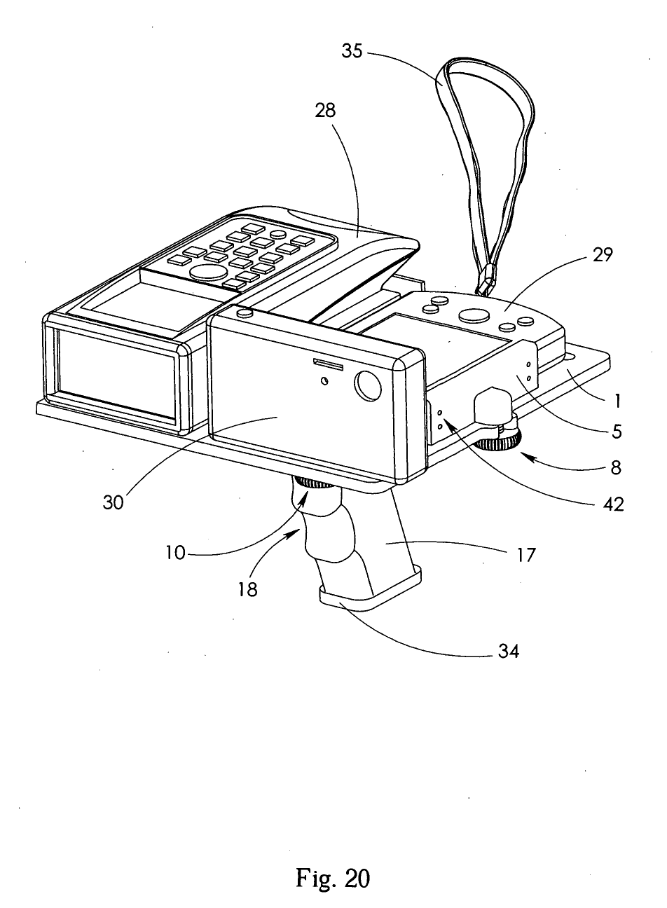

The wrist strap (35) is the strap (35), cord, or the like that is attached to the Data Gathering Platform, and may be fit around the user's wrist or hand. The wrist strap would preferably be attached to the Data Gathering Platform at the top plate (1), as shown in FIG. 20, to afford particular protection to the instrumentation (28-31) attached to the top plate (1), should the Data Gathering Platform begin to fall or should the handle (17) become disassociated from said Platform. There may be some applications of the Data Gathering Platform where the user may wish to use a wrist strap (35) attached to the handle (17).

The VELCRO® used in some embodiments of the Data Gathering Platform may be any of the many hook and loop patches or tape available, including brands other than VELCRO®, and the grade of hook and loop materials may vary from craft grade to industrial grade, for heavier loads. Hook and loop fastening systems are for purposes of this specification and its appended claims considered to be equivalent and synonymous with hook and link, and hook and pile fastening systems. Throughout this specification and its appended claims, the term VELCRO® is also intended to include all types of hook and loop attaching means, and the like. Throughout this specification and its appended claims, the term patch, as with VELCRO® patch (38) or hook and loop patch (38), is intended to also refer to VELCRO® tapes or hook and loop tapes, as well.

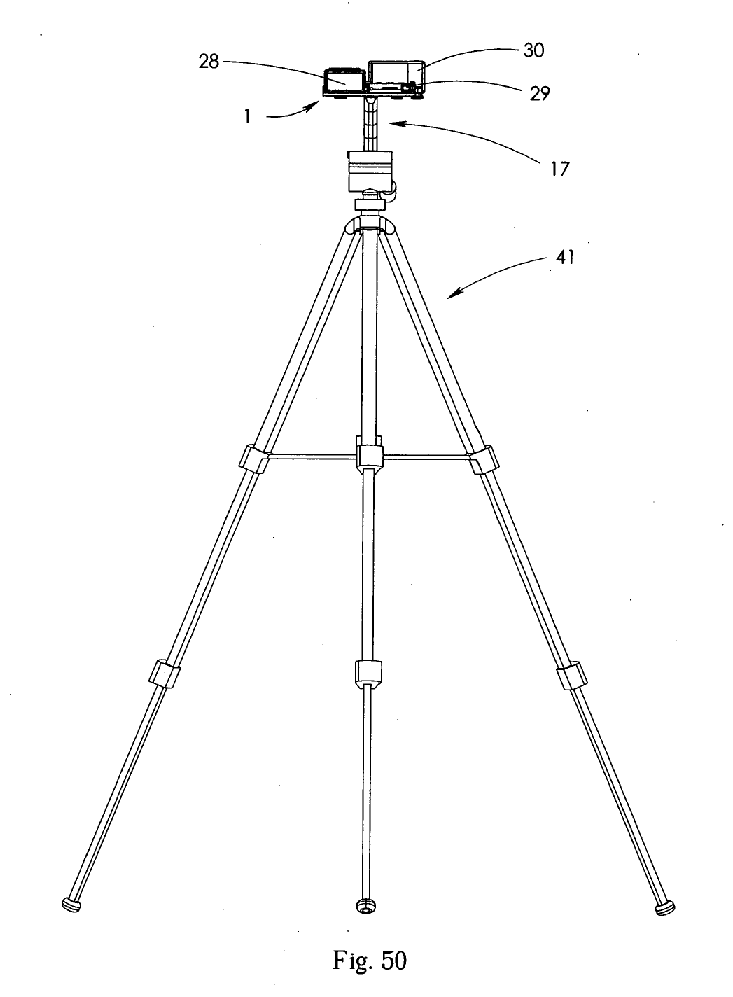

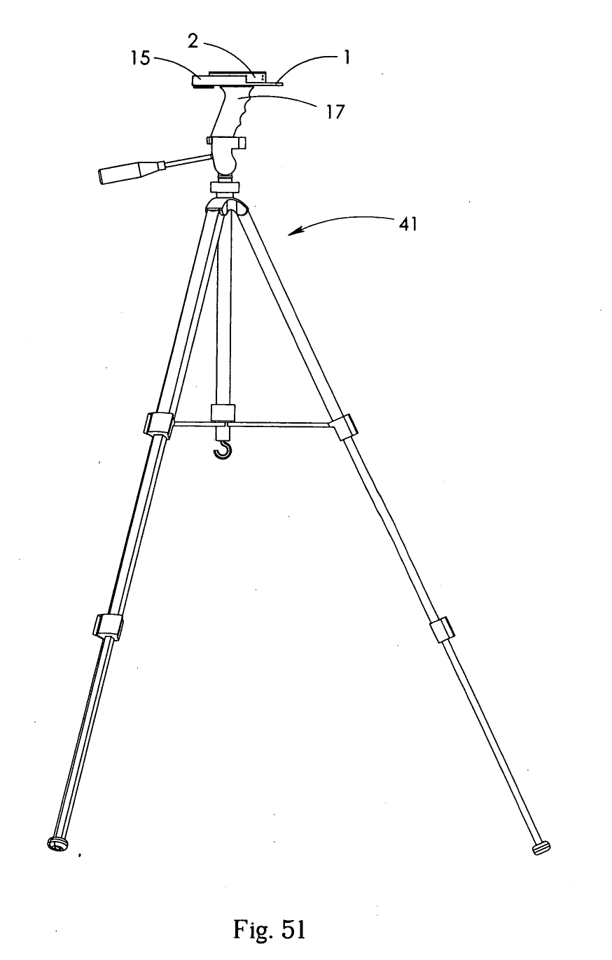

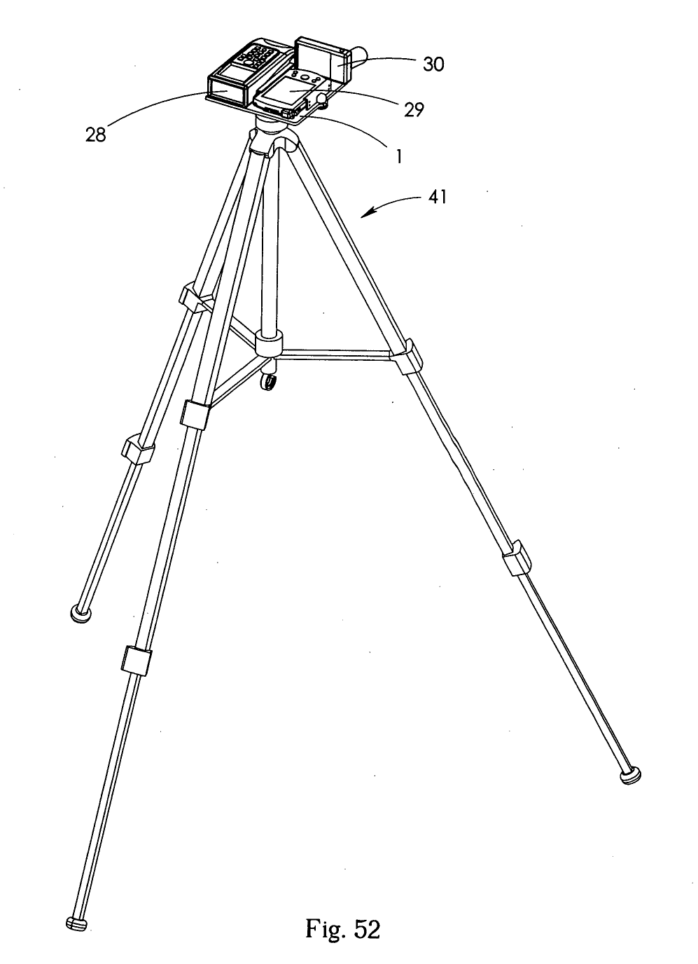

The Data Gathering Platform may be attached to a tripod (41) at a number of places, and for some special applications and needs of the user. There are three viable places where the Data Gathering Platform may be attached to a tripod (41). The first place where a tripod (17) may be attached to the Data Gathering Platform is into a screw port optionally located on the bottom surface of the handle (17) and shown in FIGS. 50 and 51, said screw port optionally having a screw insert, similar to the clamp screw insert (7) described above. The insert (7) may be composed essentially of brass, aluminum, steel, or another reliable and hard material. The second place where a tripod (17) may be attached to the Data Gathering Platform is into the screw port for the measuring device (28), thereby sandwiching the top plate (1) and securing the Data Gathering Platform onto the tripod (41), as shown in FIG. 52. The third place where a tripod (41) may be attached to the Data Gathering Platform is into the screw port for the camera (30), thereby sandwiching the top plate (1) and securing the Data Gathering Platform onto the tripod (41), and in much the same manner as was shown in FIG. 52.

### DETAILED DESCRIPTION OF THE INVENTION

The various embodiments described below and elsewhere in the specification, and throughout the drawing figures, and each of them, thereto, are intended to describe and illustrate some of the simplest and primordial set of components, and some preferred and modified examples of certain components and embodiments are shown and described to illustrate higher levels of design engineering of the inventive concepts devised by the inventor, Mark Willard Vejnar. The present broad disclosure is intended to cover and protect derivative embodiments that may be comprised of modifications of said components, or by eliminations or additions to the embodiments, or by hybridization of a plurality of embodiments.

Data Gathering Platform without Handle

The simplest embodiments of the Data Gathering Platform are comprised essentially of a top plate (1) with various means of affixing the desired instruments and devices upon the top plate's (1) top surface.

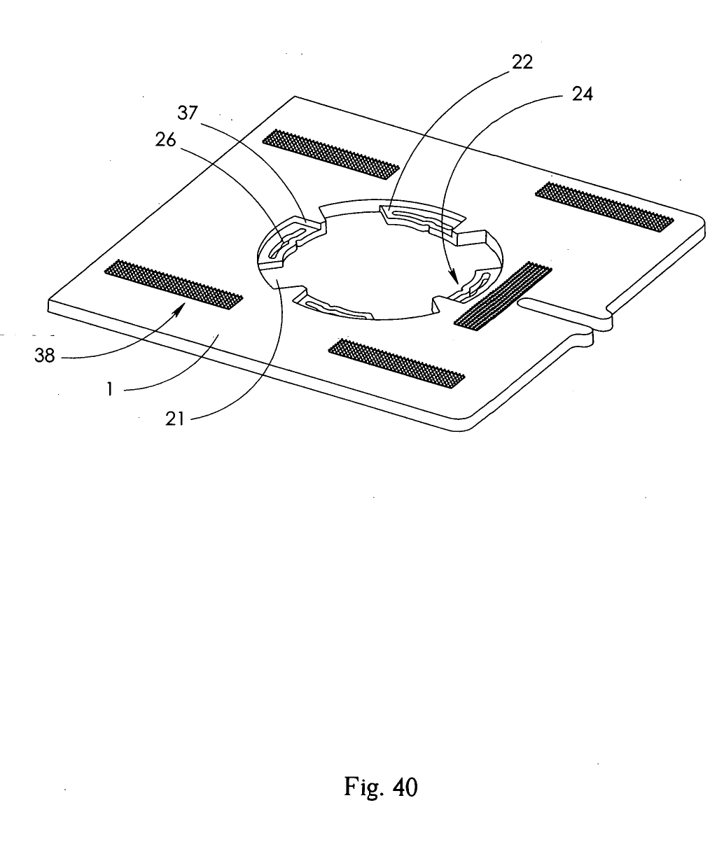

The simplest means of affixing the instruments and devices to the top plate (1) would be to use a hook and loop fastening system, such as a VELCRO® system, to affix said instruments and devices, and where for each instrument and device, a hook or loop patch (38) would be affixed to the desired position on the top surface of the top plate (1), and the opposite type of hook or loop patch (38) would be affixed to the bottom of the instrument or device, so that the two patches could matedly bond, thereby affixing the instrument or device to the top surface of the top plate (1), and in the desired position, as shown in FIG. 40.

A second simple means for affixing the instruments and devices to the top surface of the top plate (1) is through the use of screw fittings for the measuring device (28) and for the camera (30), and through the use of a VELCRO® system or hook and loop patch (38) for affixing the handheld computer to the top plate (1). The screw fittings would include one or more camera screw orifices (11, 12) and a camera screw (10) that fits through a camera screw orifice (11, 12), and into the screw port found on most better cameras (30), and more often used to place a camera on a tripod. The screw fittings would also include a measuring device screw (13) that would fit through the measuring device screw orifice (14), and into the screw port found on most better quality measuring tools (e.g., 28). The tightening of the screw fittings secures and affixes the instruments and devices in place on the top plate (1) for their effective use.

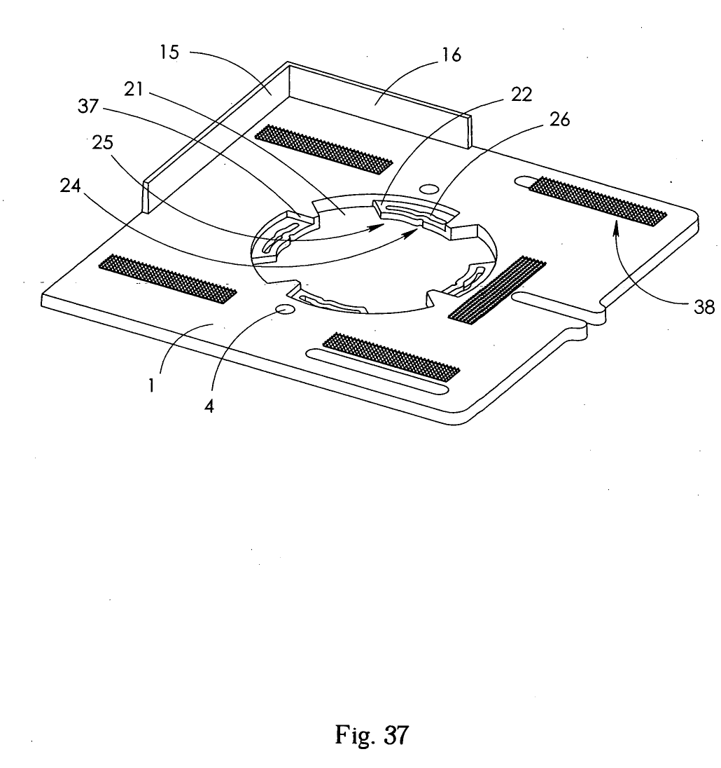

A third means for affixing the instruments and devices to the top plate (1) is through the use of screw fittings to affix the measuring instrument (28) and the camera (30) to the top plate (1), and a set of clamps, such as the stationary clamp (2) and the adjustable clamp (5), to affix the handheld computer (29) to the top plate (1). A modified embodiment may also include a measuring device stabilizer wall (15) and a back wall (16), to further hold the measuring device (28) securely in place, as shown in FIG. 37.

Data Gathering Platform with Handle

The handle (17) is located at the bottom of the top plate (1), and preferably near the middle of the top plate (1). The handle (17) may be permanently affixed to the top plate (1), as is shown in FIGS. 25-30, and 35, 38, 42-43, and 47-49, or it may be detachable or hinged, as further described below, infra. A permanently affixed handle (17) may be affected by molding the Data Gathering Platform with Handle, as one unit, or the handle (17) may be permanently affixed to the top plate (1), after the molding or manufacturing process, and by a glue-fitting, sono-welding, rivets, or some other means of affixing the handle (17) to the top plate (1). The several embodiments immediately below may have the handle (17) permanently affixed to the top plate (1) by any of the methods, as their result is essentially equivalent.

Another set of embodiments of the Data Gathering Platform are comprised essentially of a top plate (1) with a handle (17) attached thereto. The handle (17) is attached at the bottom of the top plate (1). There are a variety of means of affixing the desired instruments and devices upon the top plate's (1) top surface. The simplest means of affixing the desired instruments and devices to the top plate (1) would be to use a hook and loop fastening system of patches (38), such as a VELCRO® system, to affix said instrument and devices, and where for each instrument and device, a hook or loop patch (38) would be affixed to the desired position on the top surface of the top plate (1), and the opposite type of hook and loop patch (38) would be affixed to the bottom surface of the instruments or devices to be affixed to the top plate (1), so that the instrument or device patch (38) could mately bond to the patch (38) affixed to the desired position on the top plate (1), thereby affixing the instrument or device to the top surface of the top plate (1). An example of this sort of embodiment is shown in FIG. 38.

A second simple means for affixing the instruments and devices to the top surface of the top plate (1) is through the use of screw fittings for the measuring device (28) and for the camera (30), and through the use of a hook and loop patch system (38) for affixing the handheld computer (29) to the top plate (1). The screw fitting would include one or more camera screw orifices (11, 12) and a camera screw (10) that fits through a camera screw orifice (11, 12), and into the screw port found on most better cameras (30), and more often used to place a camera on a tripod. The screw fittings would also include a measuring device screw (13) that would fit through the measuring device screw orifice (14), and into the screw port found on most better quality measuring tools. The tightening of the screw fittings secures and affixes the instruments and devices in place in their desired position on the top plate (1), for their effective use.

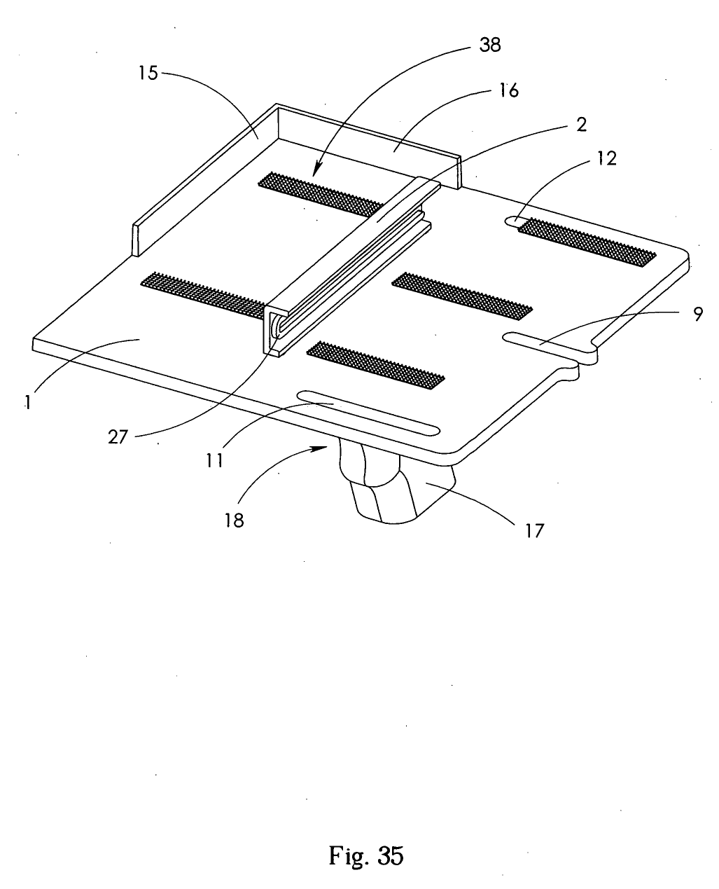

A third means for affixing the instruments and devices to the top plate (1) is through the use of screw fittings to affix the measuring instrument (28) and the camera (30) to the top plate (1), and a set of clamps, such as the stationary clamp (2) and the adjustable clamp (5), to affix the handheld computer (29) to the top plate (1). A modified simple embodiment may also include a measuring device stabilizer wall (15) and a back wall (16), to further hold the measuring device (28) securely in place, as shown in FIG. 35.

Data Gathering Platform with Detachable Handle

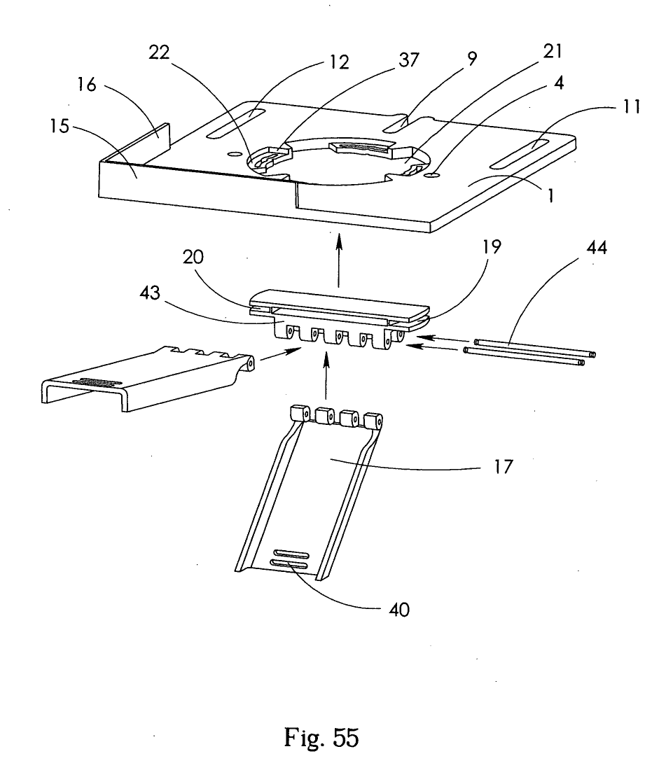

The handle (17) is located at the bottom of the top plate (1), and preferably near the middle of the top plate (1). The handle (17) may be permanently affixed to the top plate (1), as is described above in the various embodiments, or the handle (17) may be detachable, as is shown in the preferred embodiment, and its variant embodiments described immediately below, and shown in FIGS. 1-24, 36, 39, and in FIG. 55, for a detachable hinged handle (17). The detachable handle (17) may also be alignable in varying positions, and typically four different positions in the preferred embodiment. There are a variety of handle (17) types that may be used, but a pistol grip handle (17) with finger grips (18) is preferred, as shown in FIG. 45. The preferred pistol grip handle (17) would be inclined at approximately 110 degrees from the front end of the handle (17), for optimal ergonomic usage, as shown in FIG. 45. The pistol grip handle (17) would preferably have approximately four finger grips (18) or finger channels, as shown in FIG. 45, to allow the user more control of the handle (17) and the Data Gathering Platform, and also to afford the user a safer grip of the Platform. The detachable handle (17) embodiments may be attached and detached from the top plate (1) in a variety of ways. Such detachable handle (17) embodiments may be screwed into the top plate (1) with one affixed screw or the like protruding from the top of the handle (17), and matedly screwing into a screw port or the like, to be located on the bottom surface of the top plate (1), and as shown in FIG. 59. Alternatively, a detachable handle (17) may have a flange at its connecting interface with the top plate (1), and said flange may have a plurality of screw holes that align to screw ports in the bottom surface of the top plate (1), and where screws may be screwed into the bottom surface of the top plate (1) with two or more mounting screws or the like. Some specialized embodiments of the Data Gathering Platform may use a handle (17) that is unlike a pistol grip, and may be more like a pocket, glove, or port to receive the user's hand or fingers, and with some embodiments having the palm of the hand facing up and others with the palm facing down.

The preferred embodiment of the Data Gathering Platform with Detachable Handle has an alignable handle (17) and is shown in FIGS. 1-24, 36, 39, and 53-55. This preferred embodiment of the handle (17) has a front connecting slot (19) located at the top of the handle (17), and along the front surface, and has a rear connecting slot (20) located at the top of the handle (17), and along the rear surface. The connecting slots (19, 20), located at the top of the handle (17), fit into a compatible set of slot access ports (21), located on the bottom surface of the top plate (1). Once the connecting slots (19, 20) are fit into the desired compatible set of slot access ports (21), the handle (17) must be turned or rotated about its central axis, to matedly fit a compatible handle connecting rail (22), located on the bottom surface of the top plate (1), into an aligned connecting slot (19, 20), located at the top of the handle (17). The rotation of the handle (17) continues with the slot access ports (21) moving along the handle connecting rail (22), until the side of the access port guides (36) meet the rail stop (37), thereby setting the position of the handle (17). The connecting rail (22) has a width that is essentially parallel to the top plate (1), and the width increases slightly between the beginning of the rail (22) and its terminal end at the rail stop (37). Such an increase in width may be a millimeter or two. The rotation effectively fits the handle (17) onto the top plate (1), thereby uniting the two pieces (1 and 17) into a Data Gathering Platform with Detachable Handle. Preferred embodiments of the Data Gathering Platform with Detachable Handle would have a locking mechanism to further secure the handle (17) to the top plate (1). One preferred means of effecting such a locking mechanism is to have one or more slot dimples (23) or the like, located on the top portion of the handle (17) that effectively connect the handle (17) to the bottom of the top plate (1). An optimal means of achieving this connection is to have a set of dimple ports (24) located on the bottom of the top plate (1) to matedly and snugly receive the slot dimples (23), thereby effectively locking the handle (17) and the top plate (1) together. To unlock this connection between the handle (17) and the top plate (1), the user need only grasp the top plate (1) with one hand, and the handle (17) with the other hand, and to rotate the handle about its central axis in the opposite direction used to lock the handle (17) in place. A preferred embodiment of the Data Gathering Platform with Detachable Handle would have one slot dimple (23) located in the middle of the back portion of each of the two connecting slots (19, 20), as shown in FIGS. 45, 53-54. The preferred shape of the slot dimple (23) may be ellipsoidal, semi-spherical, or semi-cylindrical, and the preferred shape of the dimple port (24) is a shape to compatibly receive the slot dimple (23). A preferred embodiment of the Data Gathering Platform would have a dimple port (24) located along the middle of the innermost edge of each handle connecting rail (22), to matedly receive a slot dimple (23). The preferred embodiments of the Data Gathering Platform have the handle (17) rotate about its central axis in a clockwise manner, to effectively set and lock the handle (17) onto the top plate (1). Some other embodiments, however, may be designed to require a counterclockwise rotation to affect setting and locking of the handle (17) to the top plate (1), and some other embodiments may locate the slot dimples (23) on the handle connecting rail (22), and to locate the dimple ports (24) on the top portion of the handle (17) that connects to the bottom of the top plate (1), thereby effectively locking the handle (17) and the top plate (1) together in a manner similar to that disclosed above. In a preferred embodiment of the Data Gathering Platform with detachable handle, each of the top plate's (1) four handle connecting rails (22) has a rail release orifice (26). The purpose of the rail release orifice (25) is to give the connection rail (22) spring-like action and sufficient flexibility to allow the slot dimple (23) to move into and out of the dimple port (24), and with appropriate rotational force by the Platform's user.

The several sets of embodiments of the Data Gathering Platform described immediately below may have the detachable handle (17) attach to the top plate (1) by any of the methods described, or the like, as their result is essentially equivalent.

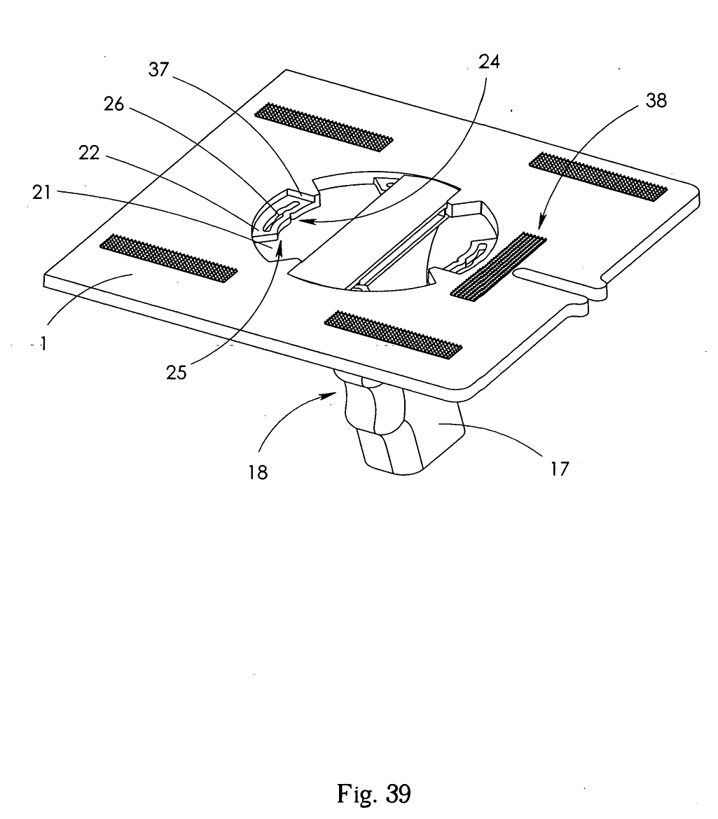

The embodiments of the Data Gathering Platform with detachable handle are comprised essentially of a top plate (1) with a detachable handle (17), that may be attached thereto, and at the bottom of said top plate (1). As with the previously disclosed embodiments, there are a variety of means of affixing the desired instruments and devices upon the top plate's (1) top surface. The first and simplest means of affixing the desired instruments and devices to the top plate (1) would be to use a hook and loop patch (38) fastening system, such as a VELCRO® system, to affix said instrument and devices, and where for each instrument and device, a hook or loop patch (38) would be affixed to the desired position on the top surface of the top plate (1), and the opposite type of hook and loop patch (38) would be affixed to the bottom of the instruments or device, so that the patch (38) could matedly affix the desired instrument or device to the desired position on the top surface of the top plate (1), as shown in FIG. 39.

A second simple means for affixing the instruments and devices to the top surface of the top plate (1) is through the use of screw fittings for the measuring device (28) and for the camera (30), and through the use of a hook and loop patch system (38) for affixing the handheld computer (29) to the top plate (1). The screw fitting would include one or more camera screw orifices (11, 12) and a camera screw (10) that fits through a camera screw orifice (11, 12), and into the screw port found on most better cameras (30), and more often used to place a camera on a tripod. The screw fittings would also include a measuring device screw (13) that would fit through the measuring device screw orifice (14), and into the screw port found on most better quality measuring tools. The tightening of the screw fittings secures and affixes the instruments and devices in place in their desired position on the top plate (1), for their effective use.

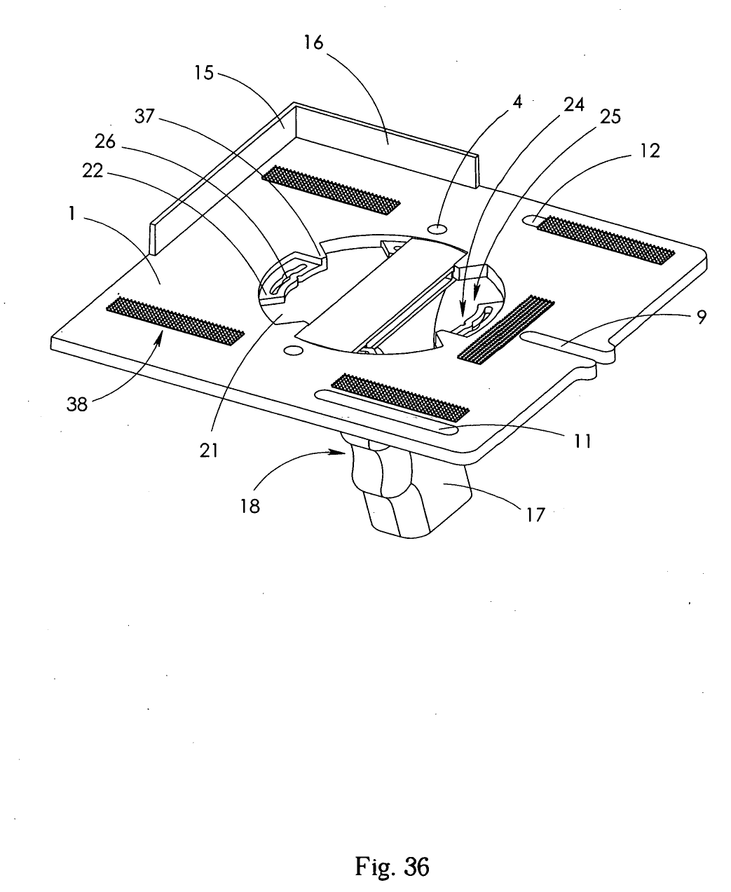

A third means for affixing the instruments and devices to the top plate (1) is through the use of screw fittings to affix the measuring instrument (29) and the camera (30) to the top plate (1), and a set of clamps, such as the stationary clamp (2) and the adjustable clamp (5), to affix the handheld computer (29) to the top plate (1). A modified simple embodiment may also include a measuring device stabilizer wall (15) and a back wall (16), to further hold the measuring device (28) securely in place, as shown in FIG. 36.

Data Gathering Platform with Hinged Handle

Another set of embodiments of the Data Gathering Platform would have a hinged handle (17), such that the handle (17) may be effectively folded up towards the bottom surface of the top plate (1), and in a preferred hinged embodiment, would open into a “butterfly” position.

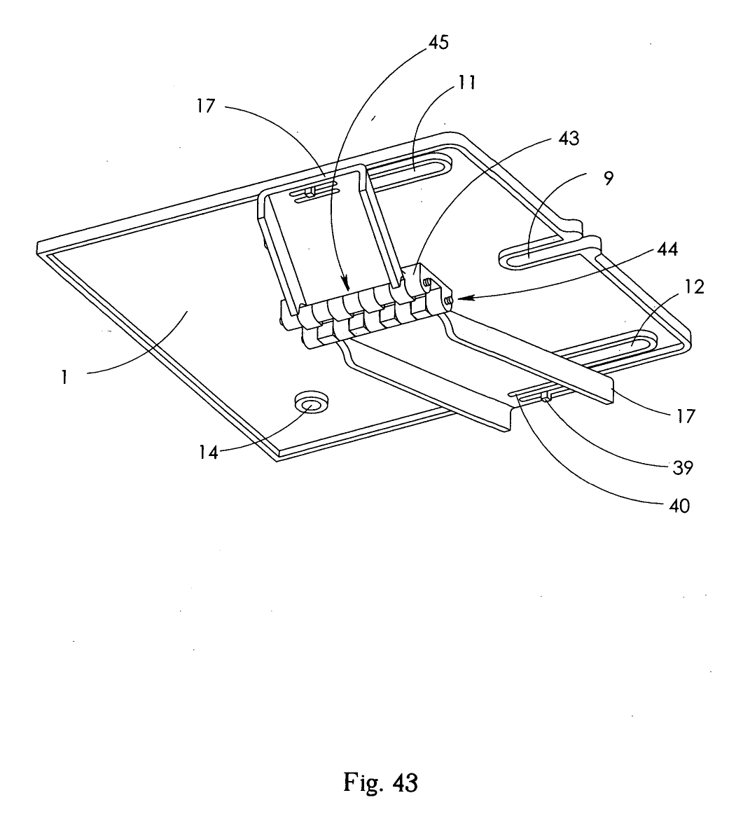

A simple embodiment of the Data Gathering Platform with Hinged Handle would have a hinge located at the front or the rear portion of the handle (17) and top plate (1) interface. This embodiment may also have a means of setting or affixing the handle (17) in place against the bottom of the top plate (1), once the hinged handle (17) is rotated, such means being a handle dimple (39) on the top surface of the handle (17), snapping into a handle dimple port (40) located on the bottom surface of the top plate (1). A modified embodiment may alternatively place the handle dimple port (40) on the handle (17), and the handle dimple (39) on the bottom surface of the top plate (1), as shown in FIGS. 42-43.

A preferred embodiment of the Data Gathering Platform with Hinged Handle would have a set of two hinges, with one hinge located along the left side and another hinge located along the right side of the handle (17) and top plate (1) interface. The handle (17) would have a parting seam preferably down the middle, and would split as with a “butterfly”, when the hinging mechanism is utilized. This embodiment, as shown in FIGS. 53-55, would have a means of setting or affixing the handle (17) in place beneath the top plate (1), once it is opened into the “butterfly” position, such means being a set of one or more handle dimples (39) located along the side and gripping region of the handle (17), and a set of handle dimple ports (40) located on the bottom surface of the top plate (1), to matedly receive said handle dimples (39), by their snapping into their mated handle dimple ports (40), and effectively locking each half of the “butterflied” handle (17) into place beneath the top plate (1), until the handle dimples (39) are pulled out of their respective handle dimple ports (40), and the “butterflied” handle (17) is re-assembled into a whole grip or handle (17) once again. Another set of handle dimples (39) and handle dimple ports may be located along the aforementioned parting seam of the handle (17), to matedly snap together and effectively affix the two butterflied sides of the handle (17) together. A modified embodiment may alternatively place the handle dimple port (40) on the handle (17), and the handle dimple (39) on the bottom surface of the top plate (1), as shown in FIG. 48.

Data Gathering Platform with Additional Mounting Supports

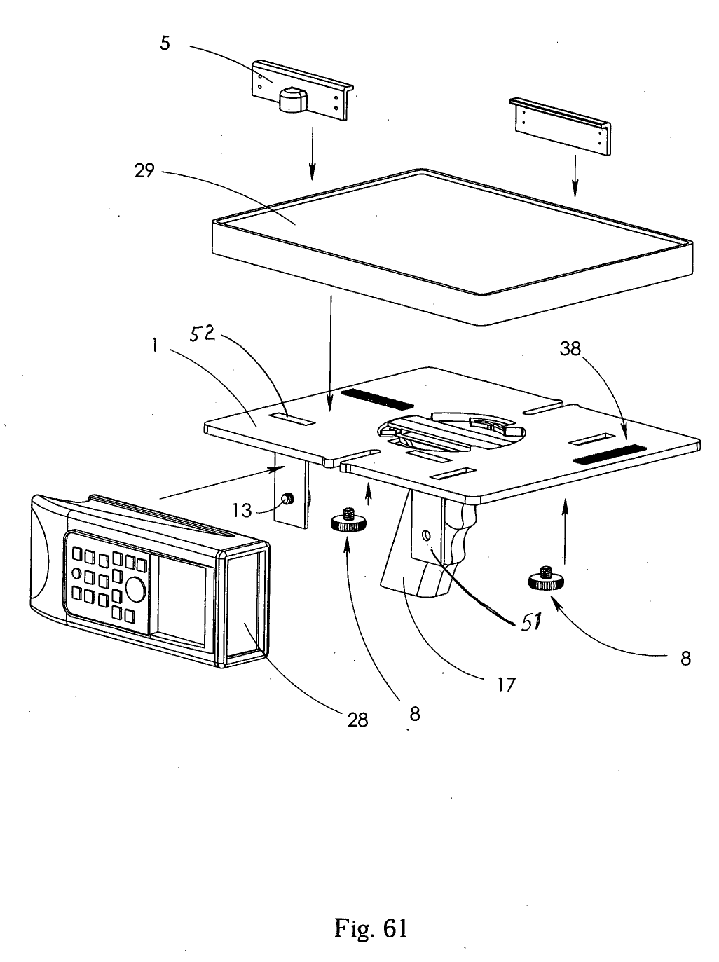

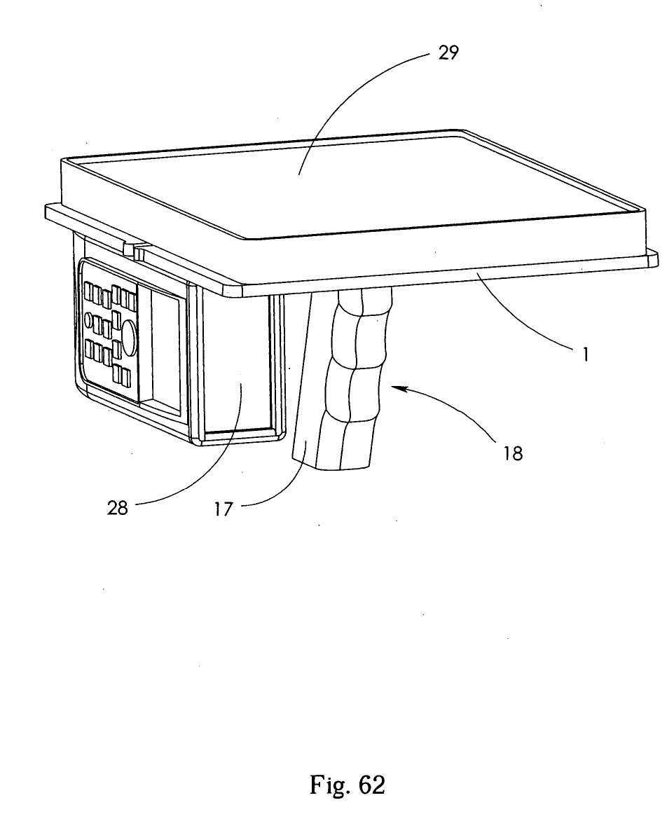

Some embodiments of the Data Gathering Platform may have mounting supports (51) for holding additional instrumentation, or for alternative instrument placement on the top plate (1), as shown in FIGS. 61 and 62. In such embodiments, the mounting supports (51) are tightly fit into mounting slots (52) located on the top plate (1), and instruments may them be affixed to the mounting supports (51), as shown in FIGS. 61 and 62. This embodiment has certain ergonomic advantages, as the key pads for the instrumentation may be located in closer and more ergonomic proximity to each other.

Data Gathering Platform Adapted for Housing Remote Activators

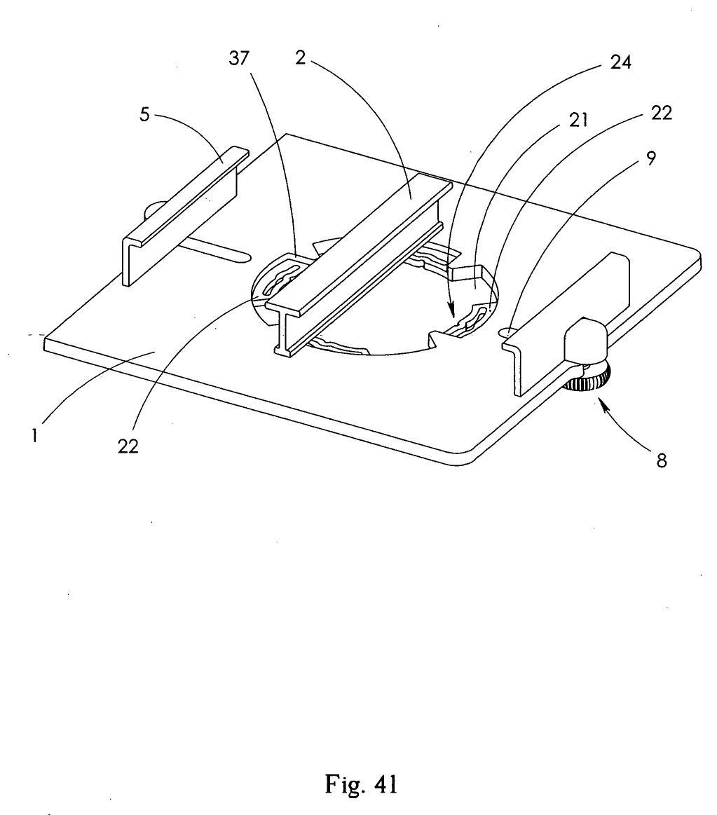

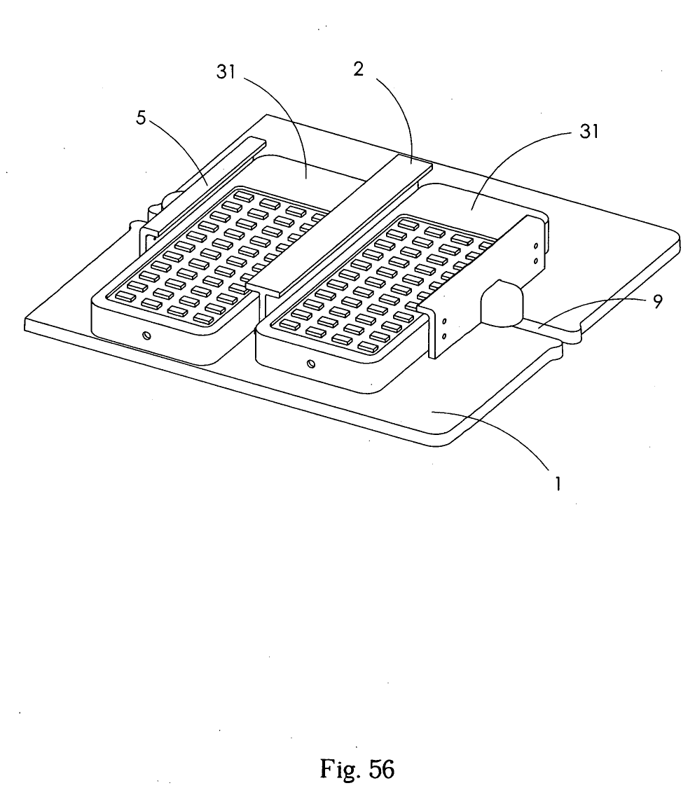

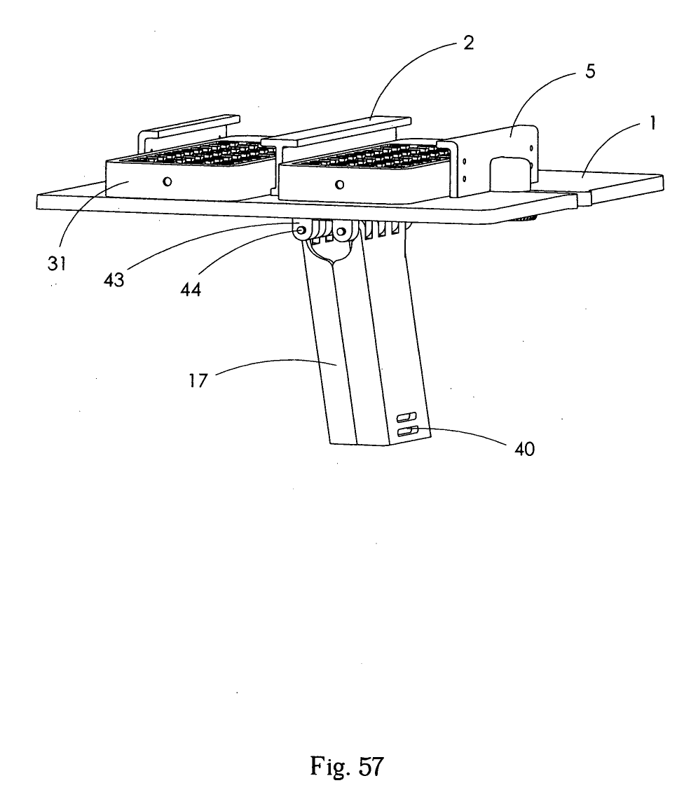

Another set of embodiments of the Data Gathering Platform are alternatively adapted for holding a set of remote activators (31). There are several varieties of this set of embodiments. A simple embodiment would be comprised of a top plate (1) with a set of hook and loop patches (38), such as a VELCRO® system, attached to the top surface of the top plate (1), and the mate or opposite type of hook and loop patch (38) attached to the bottom surface of the remote activators (31) to be affixed to the Data Gathering Platform, as shown in FIG. 38. This embodiment may have a permanently affixed handle (17), as shown in FIG. 38, a detachable handle (17), as shown in FIG. 39, a hinged handle, as shown in FIG. 43, a hinged handle (17), as shown in FIG. 57, or it may not have a handle (17), per se, as shown in FIG. 56. A preferred version of this set of embodiments would be comprised essentially of a top plate (1) with a set of adjustable clamps (5) and their mated stationary clamps (2), and with a detachable hinged handle (17), as shown in FIG. 57. In FIGS. 41 and 56, two modified embodiments are shown, with a T-style stationary clamp (2), centrally located and affixed on the top surface of the top plate (1). This stationary clamp (2) is similar to the stationary clamp utilized in the above described embodiments of the Data Gathering Platform, but this stationary clamp (2) may have a quasi-concave clamp surface on two opposite sides of the wall surface, as shown in FIGS. 41, 56 and 57. This stationary clamp (2) acts effectively as two stationary clamps (2), with each side mating to an adjustable clamp (5) that may be adjusted along a clamp screw orifice (9), with a clamp screw (8). The adjustable clamp (5) has a clamp screw housing (6) located on its bottom surface. The clamp screw housing (6) may have an optional clamp screw insert (7) therein, so that the clamp screw housing (6) may reliably and matedly receive the threaded portion of the clamp screw (8). This embodiment may securely hold two remote activators (31). This embodiment may have a permanently affixed handle (17), a detachable handle (17), a hinged handle (17), a detachable hinged handle (17), or it may not have a handle (17), per se.

Data Gathering Platform Adapted for Games and the Like.

Another set of embodiments of the Data Gathering Platform are alternatively adapted for the toys and electronic games, and may be used for holding certain toys and electronic games on the top surface of the top plate (1). The handle (17) may be used to ergonomically hold the toys or games, and the other hand may be used to operate the toys or games. Such an embodiment would have an appearance very similar to those disclosed for the Data Gathering Platform housing the measuring device (28), handheld computer (29), and camera (30).

Data Gathering Platform Adapted for Use as a Digital Video Camera Stabilizer.

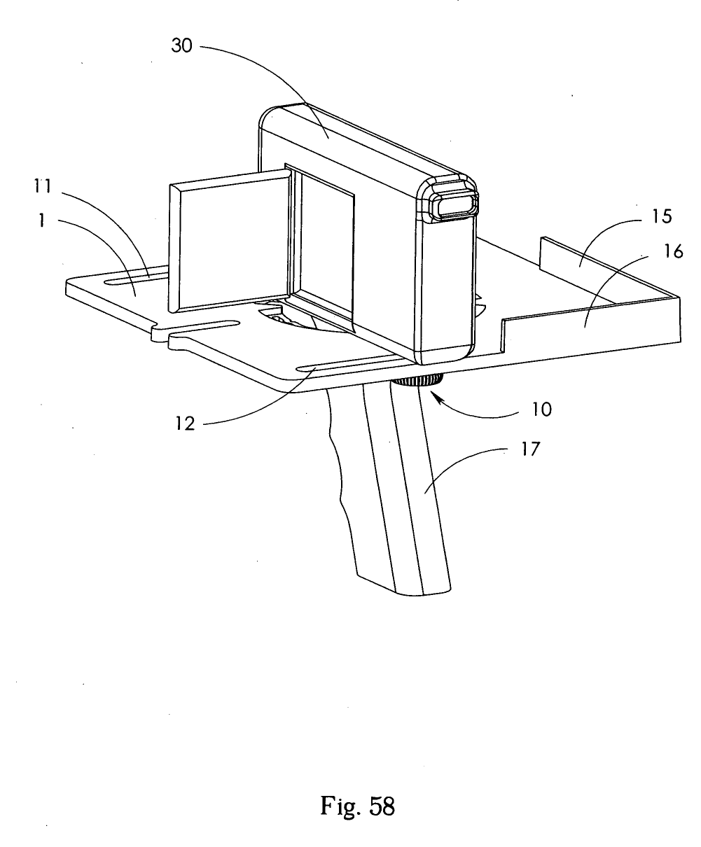

Another set of embodiments of the Data Gathering Platform are alternatively adapted for the video and movie industries, and applications using digital video and computer support for such video devices, such as law enforcement and detective agencies. The placement of a digital video camera to the top plate (1), as shown in FIG. 58, would be particularly advantageous because of their diminishing size in recent years, and their increasing software support, that may be utilized using a handheld computer (30), also attached to the top plate (1). Some embodiments of the Data Gathering Platform may have a plurality of digital movie cameras (30) attached to the top plate (1). The use of the Data Gathering Platform with handle (17) acts as a video camera stabilizer, due to its ergonomics and improved control using a pistol grip, rather than holding a video camera on its right side, as is typically done. The use of the Data Gathering Platform with handle (17) also acts as a data bundling platform, by allowing the real time wireless interface of a digital video camera with a handheld computer (30), and its video and audio support software. Such an embodiment would have an appearance similar to those disclosed for the Data Gathering Platform housing the measuring device (28), handheld computer (29), and camera (30), except a digital video camera would be attached to the top plate (1) where the measuring device (28) is shown in the embodiments described above.

Data Gathering Platform Adapted for Medical Charting and the Like.

Another set of embodiments of the Data Gathering Platform are alternatively adapted for the medical and hospital industries, and may be used for the charting of patient information, a routine procedure for nurses. Typically, charting is accomplished manually by recording a patients vital signs, such as their temperature and blood pressure, and other data on a chart. Using the Data Gathering Platform, the information may be easily carried and recorded into a handheld computer (29) affixed to the top plate (1) of the Data Gathering Platform, and the data may be downloaded into a main computer data bank as desired, or automatically using radiofrequency (rf) or microwave (mw) wireless or BLUETOOTH® technology. Other instrumentation may be added to the top plate (1), such as communications devices (a pager, walkie-talkie, or preferably a cell phone) or diagnostic instruments (a camera, digital thermometer, digital blood pressure link, or an EKG link and evaluator to receive data from rf EKG leads. Such an embodiment would have an appearance very similar to those disclosed for the Data Gathering Platform housing the measuring device (28), handheld computer (29), and camera (30).

Data Gathering Platform Adapted for Bar Code Reading and Inventory Control and the Like.

Another set of embodiments of the Data Gathering Platform are alternatively adapted for bar code reading and inventory control, where a portable bar code reader would be attached onto the top surface of the top plate (1) and in communication with a handheld computer (30) or the like, also attached to the top surface of the top plate (1). Such an embodiment would be new and useful to any situation where inventory control or the like is necessary, such as retail and wholesale businesses, assembly plants, libraries, food, drug, and chemical processing plants, and the inventory of military supplies. The bar code reader would have the appearance much like that of the measuring device (28), and would be aimed in much the same manner to affect a reading. Such an embodiment of the Data Gathering Platform would have an appearance very similar to those disclosed for the Data Gathering Platform housing the measuring device (28), handheld computer (29), and camera (30), or of the hybrid and electronically simplified embodiments described immediately below.

Further Hybrid and Electronically Simplified Embodiments

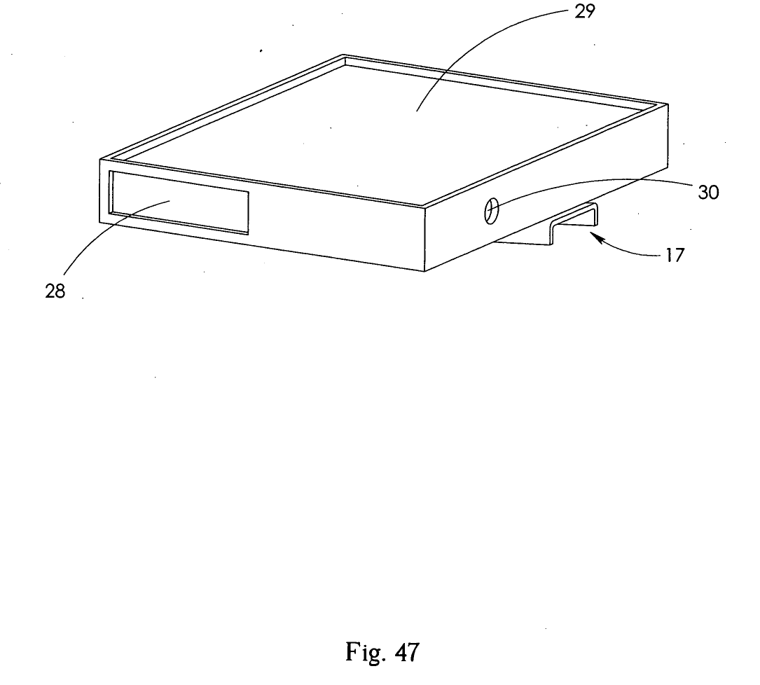

Another embodiment of the Data Gathering Platform would be a multi-functional hybrid embodiment of the Data Gathering Platform with applications in the real estate appraising and building construction industries, and comprised essentially of a handheld computer (29) or a mini-laptop computer, approximately 7 inches by 9 inches, or smaller, and with a camera (30) lens located on the side surface of the computer (29), and a laser or acoustical measuring device (28) also located on a side surface of the computer (29) or preferably on the front side, as shown in FIGS. 47-49. This embodiment effectively simplifies the above described necessity of using three instruments to accomplish a measuring (laser measuring device, 28), image recording (camera, 30), and computational task (handheld computer, 29), such that the task may be achieved with a single instrument. A modification of this hybrid embodiment of the Data Gathering Platform with applications in inventory control, would be comprised essentially of a bar code scanner located on the side surface or preferably on the front side of a handheld computer (29) or a mini-laptop computer, approximately 7 inches by 9 inches, or smaller, and with support software loaded into the computer (29), including bar code software and inventory data. This embodiment also effectively simplifies the devices used in a complete inventory control system or subsystem, such that the task may be achieved with a single instrument multi-function hybrid embodiment described immediately above.

While I have shown and described in this disclosure and its appended drawing figures, and which are a part of and incorporated in said disclosure, only selected embodiments in accordance with the present invention, it is understood that the same is not limited thereto, but is susceptible to numerous changes and modifications as known to one having ordinary skill in the art, and I therefore do not wish to be limited to the details shown and described herein, but intend to cover all such modifications, changes, eliminations, combinations and hybrids, as are encompassed by the scope of the appended claims.

I claim:

1-10. (canceled)

11. A Data Gathering Platform comprised essentially of a top plate with a stationary clamp attached to said top plate, and an adjustable clamp attached to the top plate with a screw fitting.

12. A Data Gathering Platform, as recited in claim 11, and further comprised essentially of a plurality of screw ports located on said top plate.

13. A Data Gathering Platform, as recited in claim 11, and further comprised essentially of a handle attached to the top plate.

14. A Data Gathering Platform, as recited in claim 12, and further comprised essentially of a handle attached to the top plate.

15. A Data Gathering Platform, as recited in claim 13, wherein said handle is detachable from said top plate.

16. A Data Gathering Platform, as recited in claim 14, wherein said handle is detachable from said top plate.

17. A Data Gathering Platform, as recited in claim 13, wherein said handle is hinged near the interface between the handle and said top plate, and said handle may be rotated about a hinge axis of rotation to a closed position, with the handle adjacent to the top plate.

18. A Data Gathering Platform, as recited in claim 14, wherein said handle is hinged near the interface between the handle and said top plate, and said handle may be rotated about a hinge axis of rotation to a closed position, with the handle adjacent to the top plate.

19. A Data Gathering Platform, as recited in claim 17, wherein said handle is hinged to separate into two halves that may each be folded adjacent to said top plate.

20. A Data Gathering Platform, as recited in claim 18, wherein said handle is hinged to separate into two halves that may each be folded adjacent to said top plate.

21. A Data Gathering Platform, as recited in claim 13, wherein said handle has an overmold surface.

22. A Data Gathering Platform, as recited in claim 13, wherein said clamps have an overmold surface.

23. A Data Gathering Platform, as recited in claim 13, wherein said handle has a handle cavity and a handle cavity cover.

24. A Data Gathering Platform, as recited in claim 11, wherein
a. there are a plurality of said adjustable clamps, and
b. said stationary clamp has a quasi-concave clamp surface on opposite sides of the stationary clamp.

25. A Data Gathering Platform comprised essentially of:
a. a top plate with hook and loop fastener covering a portion of said top plate, and
b. a detachable handle, attached to the top plate.

26. A Data Gathering Platform comprised essentially of:
a. a top plate with hook and loop fastener covering a portion of said top plate, and
b. a handle that is hinged at the interface between said handle and the top plate, and the handle may be rotated about a hinge axis of rotation, to a closed position with said handle adjacent to said top plate.

27. A Data Gathering Platform, as recited in claim 26, wherein the handle may be attached to the top plate with a handle screw fitting.

28. A Data Gathering Platform, as recited in claim 16, wherein the handle may be attached to the top plate with a handle screw fitting.

29. A Data Gathering Platform, as recited in claim 26, wherein:
a the handle has a front connecting slot located at the top of said handle, and
b. a rear connecting slot also located at the top of the handle, and
c. said front connecting slot and said rear connecting slot matedly fit into a compatible set of slot access ports located on the bottom surface of said top plate, and said handle is then rotated about its central axis along a set of handle connecting rails to affect an attachment to said top plate.

30. A Data Gathering Platform, as recited in claim 16, wherein:
a. the handle has a front connecting slot located at the top of said handle, and
b. a rear connecting slot also located at the top of the handle, and
c. said front connecting slot and said rear connecting slots matedly fit into a compatible set of slot access ports located on the bottom surface of the top plate, and said handle is then rotated about its central axis along a set of handle connecting rails to affect an attachment to said top plate.

31. A Data Gathering Platform, as recited in claim 29, wherein there are a plurality of compatible sets of slot access ports and said associated handle connecting rails to receive the connecting slots, thereby permitting said Data Gathering Platform to be alignable in any of a plurality of directions, by varying the position of the handle in relation to the position of the top plate.

32. A Data Gathering Platform, as recited in claim 30, wherein there are a plurality of compatible sets of slot access ports and said associated handle connecting rails to receive the connecting slots, thereby permitting said Data Gathering Platform to be alignable in any of a plurality of directions, by varying the position of the handle in relation to the position of the top plate.

33. A Data Gathering Platform, as recited in claim 31, wherein:
a. the handle connecting rails each have a rail stop at their terminal end, and
b. a handle locking means comprised of a slot dimple located in the back portion of each said two connecting slots, and a dimple port located along the innermost edge of each said handle connecting rails, said dimple port to matedly receive said slot dimple, by a rotation of said handle about its central axis, and into a locking position.

34. A Data Gathering Platform, as recited in claim 32, wherein:
a. the handle connecting rails each have a rail stop at their terminal end, and
b a handle locking means comprised of a slot dimple located in the back portion of each said two connecting slots, and a dimple port located along the innermost edge of each said handle connecting rails, said dimple port to matedly receive said slot dimple, by a rotation of said handle about its central axis, and into a locking position.

35. A Data Gathering Platform, comprised essentially of:
a. a top plate with a hybrid electronic instrument incorporated on said top plate,
b. said hybrid electronic instrument is essentially a computer with image capturing capability and a camera lens located on a side surface of the hybrid electronic instrument, and
c. said hybrid electronic instrument also has a distance measuring capability and a measuring lens located on a side of the hybrid electronic instrument.

36. A Data Gathering Platform, as recited in claim 35, and further comprised of a handle attached to the top plate.

37. A Data Gathering Platform, as recited in claim 36, wherein said handle is detachable from said top plate.

38. A Data Gathering Platform, as recited in claim 36, wherein said handle is hinged to separate into two halves that may each be folded adjacent to the top plate.

39. A Data Gathering Platform, as recited in claim 37, wherein said handle is hinged to separate into two halves that may each be folded adjacent to the top plate.
